(19) United States
(12) Patent Application Publication
(10) Pub. No.: US 2026/0239896 A1
(43) Pub. Date: Aug. 13, 2026

(54) DEVICE AND METHOD FOR OPERATING A SEMICONDUCTOR SPIN QUBIT QUANTUM COMPUTER

(71) Applicants: RHEINISCH-WESTFÄLISCHE TECHNISCHE HOCHSCHULE (RWTH) AACHEN, Aachen (DE); FORSCHUNGSZENTRUM JÜLICH GMBH, Jülich (DE)

(72) Inventors: Jan Klos, Aachen (DE); Matthias Künne, Aachen (DE); Pascal Cerfontaine, Jülich (DE)

(21) Appl. No.: 19/154,098

(22) PCT Filed: Mar. 9, 2023
(86) PCT No.: PCT/EP2023/056093

§ 371 Date: Aug. 6, 2025

(30) Foreign Application Priority Data
Feb. 28, 2023 (WO) PCT/EP2023/055057
Feb. 28, 2023 (WO) PCT/EP2023/055058
Feb. 28, 2023 (WO) PCT/EP2023/055059
Feb. 28, 2023 (WO) PCT/EP2023/055060
Feb. 28, 2023 (WO) PCT/EP2023/055061

(51) Int. Cl. H10N 99/00; G06N 10/40; H10N 50/20

(52) U.S. Cl. CPC H10N 99/05; G06N 10/40; H10N 50/20

(57) ABSTRACT

A method of operating a quantum chip comprising the steps of calibrating voltage parameters pertaining to voltages to be applied to the plurality of gate electrodes, selecting a path along selected ones of a plurality of shuttling lanes between a position of a qubit and a selected manipulation zone, determining at least one shuttling voltage time course to be applied to an associated subset of the plurality of gate electrodes to move the qubit from the current position to the selected manipulation zone, moving the qubit along the selected ones of the plurality of shuttling lanes from the current position to the selected manipulation zone by applying the shuttling voltage time courses, determining, for the selected manipulation zone a manipulation voltage time course to be applied to the associated subsets of the plurality of gate electrodes to manipulate the qubit, and manipulating the qubit at the selected manipulation zone.

### FIELD OF THE DISCLOSURE

The field of the present disclosure relates to the operation of quantum processors.

### BACKGROUND OF THE DISCLOSURE

Quantum processor architectures have to allow for scalability in order to achieve numbers of logical qubits sufficiently high to implement quantum computer chips that enable NISQ (noisy intermediate-scale quantum) era quantum computing or even universal quantum computing. In the case of spin qubit-based quantum computing, the qubits are arranged in a two-dimensional plane. A downside of this two-dimensional architecture is the so-called fan-out problem, i.e., spatial requirements of the wiring for the control lines of the quantum processor between the quantum processor and a classical control circuit. These spatial requirements scale faster with the number of qubits than the size of the hitherto proposed spin qubit-based quantum processor architectures.

Recently, an architecture for spin-qubits based on direct electron shuttling in Si/SiGe semiconductor heterostructures was proposed. The architecture includes shuttling paths along which qubits are transportable across, in principle, arbitrary distances such as of up to about 50 μm. The shuttling paths allow to arrange components of the quantum processor, such as loading zones, readout zones, and manipulation zones, at a distance from each other, which lowers crosstalk. Providing shuttling paths also enables operations modes that require comparatively small operation frequencies and reduced local magnetic field gradients.

In these shuttling path-based architectures, high-fidelity shuttling is important for reliable computations. Such high-fidelity shuttling is compromised by, e.g., charge defects or low valley splitting along the shuttling path. The low valley splitting may lead to leakage out of the computational basis, e.g., two spin states, that is used for computation.

There is a need for identifying spots in the quantum processor, e.g., in the shuttling path or other components of the quantum processor, where the reliability of qubit handling is reduced, which ultimately impacts on the performance of the quantum processor.

### SUMMARY OF THE DISCLOSURE

A method, using a microprocessor, of operating a quantum chip (10),

wherein the quantum chip comprises a semiconductor heterostructure (12) and a plurality of gate electrodes (50) arranged on the semiconductor heterostructure (12) to provide a plurality of shuttling lanes (16) for moving a plurality of qubits along a plurality of paths (45);

the plurality of gate electrodes (50) are further arranged to form a plurality of manipulation zones (20) and a plurality of T-junctions (18),

any one of the plurality of manipulation zones (20) comprising an interface (25), at which two of the plurality of shuttling lanes (16) meet one another, and

any one of the plurality of T-junctions (18) comprising a junction (28), at which one of the plurality of shuttling lanes (16) joins another one of the plurality of shuttling lanes (16);

the method comprising the steps of

calibrating voltage parameters pertaining to voltages to be applied to the plurality of gate electrodes (50), the parameters pertaining to one or more subgroups of the plurality of gate electrodes (50);

selecting a path (45s) along selected ones (16-1, 16-2, . . . , 16-n) of the plurality of shuttling lanes (16) between a position (S) of a qubit and a selected manipulation zone (20);

determining, based on the voltage parameters, for any one of the selected ones (16-1, 16-2, . . . , 16-n) of the plurality of shuttling lanes (16), at least one shuttling voltage time course to be applied to the associated subset (50i) of the plurality of gate electrodes (50), to move the qubit from the current position to the selected manipulation zone (20);

moving the qubit along the selected ones (16-1, 16-2, . . . , 16-n) of the plurality of shuttling lanes (16) from the current position(S) to the selected manipulation zone (20), by applying the shuttling voltage time courses to subsets (50-1, 50-2, . . . , 50-n) of the plurality of gate electrodes (50), associated with the selected ones (16-1, 16-2, . . . , 16-n) of the plurality of shuttling lanes (16);

determining, based on the voltage parameters, for the selected manipulation zone (20), a manipulation voltage time course to be applied to the associated subsets (50-n, 50-s) of the plurality of gate electrodes (50), to manipulate the qubit; and

manipulating the qubit at the selected manipulation zone (20) by applying at least one manipulation voltage time course to the subsets (50-n,50-s) of the plurality of gate electrodes (50), associated with the selected manipulation zone (20).

The method of claim 1, wherein the manipulating of the qubit comprises performing a single-qubit action on the qubit.

The method of claim 1 or 2, wherein the manipulating of the qubit comprises performing a two-qubit action on the qubit and a second qubit positioned at the selected manipulation zone (20).

The method of any one of claims 1 to 3, further comprising moving the qubit to the position (S).

The method of any one of claims 1 to 4, wherein the path (45s) is selected such that at least two of the selected ones (16-1, 16-2, . . . , 16-n) of the plurality of shuttling lanes (16) meet at the interface (25) of at least one interposed one (20) of the plurality of manipulation zones (20), or join at the junction (28i) of at least one interposed one (18) of the plurality of T-junctions (18).

The method of any one of claims 1 to 5, further comprising moving a third qubit, positioned at the selected manipulation zone (20), from the selected manipulation zone (20) by applying at least one further shuttling voltage time course to the subsets (50-n,50-s) of the plurality of gate electrodes (50), associated with the selected manipulation zone (20).

The method of claim 6, wherein the moving of the third qubit, positioned at the selected manipulation zone (20), comprises moving the third qubit past the interface (25) of the selected manipulation zone (20).

The method of any one of claim 1 to 7, moving another qubit along further selected ones (16-1′, 16-2′, . . . , 16-n′) of the plurality of shuttling lanes (16), by applying the shuttling voltage time courses to further subsets (50-1′, 50-2′, . . . , 50-n′) of the plurality of gate electrodes (50), associated with the further selected ones (16-1′, 16-2′, . . . , 16-n′) of the plurality of shuttling lanes (16).

The method of any one of claims 1 to 8, further comprising manipulating the other qubit at a further manipulation zone (20′), by applying the at least one manipulation voltage time course to further subsets (50-n′,50-s′) of the plurality of gate electrodes (50), associated with the further manipulation zone (20′.)

The method of any one of claim 1 to 9, further comprising coordinating the applying of the shuttling voltage time courses, the applying of the manipulation voltage time course, and the applying of the at least one further shuttling voltage time course.

The method of claim 10, further comprising coordinating further voltage time courses applied to other ones of the plurality of gate electrodes (50).

The method of any one of claim 1 to 10, further comprising recalibrating and/or adjusting the voltage parameters.

The method of any one of claim 1 to 12, further comprising improving a coherence of one of the qubits.

The method of claim 13, wherein the improving of the coherence comprises applying dynamical decoupling, e.g., applying a Car-Purcell-Meiboom-Gill pulse.

A computing system comprising a quantum processor (10), a voltage source, and a microprocessor,

the quantum chip comprising a semiconductor heterostructure (12) and a plurality of gate electrodes (50) arranged on the semiconductor heterostructure (12), wherein

the plurality of gate electrodes (50) are arranged to provide a plurality of manipulation zones (20) for manipulating a plurality of qubits, a plurality of T-junctions (18) for interconnecting the plurality of qubits, and a plurality of shuttling lanes (16) which provide a plurality of paths (45) along which the plurality of qubits are movable, and

the plurality of manipulation zones (20) are interconnected by the plurality of paths (45) and the plurality of T-junctions (18),

the voltage source being electrically connected to the plurality of gate electrodes (50) to apply voltages to the plurality of gate electrodes (50) for manipulating the plurality of qubits, for interconnecting the plurality of qubits, and/or for moving the plurality of qubits; and

the microprocessor being communicatively connected to the voltage source for controlling the voltages and comprising a memory storing voltage parameters for voltages to be applied, the parameters pertaining to one or more subgroups of the plurality of gate electrodes (50).

The computing system of claim 15, wherein any one of the plurality of manipulation zones (20) has an interface (25), at which two meeting ones of the plurality of shuttling lanes (16) meet one another.

The computing system of claim 16, wherein ones of the manipulation zone (20) further comprise at least one plunger gate and/or at least one barrier gate at the interface (25) The computing system of any one of claims 15 to 17, wherein any one of the plurality of T-junctions (18) has a junction (28) at which two joining ones of the plurality of shuttling lanes (16) join one another.

The computing system of claim 18, wherein ones of the plurality of T-junctions (18) further comprise at least one plunger gate and/or at least one barrier gate at the junction (28).

The computing system of any one of claims 15 to 19, wherein at least one of the plurality of manipulation zones (16) further comprises a top gate (50d).

The computing system of any one of claims 15 to 20, wherein the voltage source is configured to provide at least one DC voltage and/or at least one AC voltage.

The computing system of any one of claims 15 to 21, wherein the quantum processor (10) is arranged at a first cryogenic temperature.

The computing system of any one of claims 15 to 22, wherein the microprocessor is arranged at an ambient temperature or at a second cryogenic temperature, the second cryogenic temperature being equal to, or different from, the first cryogenic temperature.

The computing system of any one of claims 15 to 23, wherein the plurality of gate electrodes (50) are arranged on the semiconductor heterostructure (12) in a periodic manner.

System comprising the computing system of one of claims 15 to 24 and an external magnet for providing an external magnetic field B₀.

### BRIEF DESCRIPTION OF THE DRAWINGS

FIG. 1 shows a top view of a quantum processor.

FIG. 2 shown a top view of a unit cell of the quantum processor shown in FIG. 2.

FIG. 3A shows a top view of an aspect of a shuttling lane.

FIG. 3B shows a longitudinal cross-section of a further aspect of the shuttling lane.

FIG. 3C shows a pair of path-defining gates arranged at a path for a qubit.

FIG. 3D shows a longitudinal cross-section of a further aspect of the shuttling-lane.

FIG. 4A shows a top view of an aspect of a shuttling lane with a segmented path-defining gate electrode.

FIG. 4B shows a longitudinal cross-section of a further aspect of the shuttling lane.

FIG. 4C shows a pair of segmented path-defining gates arranged at a path for one or more qubits.

FIG. 5 shows an example of a grayscale-coded valley-splitting landscape of a shuttling lane as well as possible trajectories for a qubit along the shuttling lane which circumvent a series of fidelity-reducing loci with reduced valley splitting.

FIG. 6A shows a top view of a T-junction.

FIG. 6B shows a top view of the path-defining gates of the T-junction shown in FIG. 6A.

FIG. 7 shows a simulation of the orbital splitting during movement past a junction during straight moving (left panel) and during diversion at the junction.

FIG. 8 shows a simulation of potential well at the T-junction during diverting at least one qubit the junction.

FIG. 9 shows another aspect of a segmented path-defining gate.

FIG. 10A shows a top view of a T-junction with a segmented path-defining gate.

FIG. 10B shows a top view of the segmented path-defining gates of the T-junction shown in FIG. 6A.

FIG. 11A shows a top view of an aspect of a manipulation zone.

FIG. 11B shows a longitudinal cross-section of a further aspect the manipulation zone.

FIG. 11C shows a longitudinal cross-section of a further aspect of the manipulation zone.

FIG. 11D shows a longitudinal cross-section of a further aspect of the manipulation zone.

FIG. 11E shows a line cut of a temporal sequence of a simulation of an evolution of a potential energy landscape at the interface of a manipulation zone.

FIG. 12 shows in the upper panel an effect on a shuttling voltage of applying adjustment voltage for changing a confinement of a qubit. FIG. 4 shows in the lower panel an effect on a shuttling voltage of applying adjustment voltage for shifting a confinement a qubit.

FIG. 13A shows another aspect of quantum processor according to the disclosure.

FIG. 13B shows a unit cell of the quantum processor shown in FIG. 13B.

### DETAILED DESCRIPTION

The present disclosure relates to a method of operating a quantum processor as well as to a method of manufacturing a quantum processor.

The quantum processor may operate based on spin qubits. A spin qubit is a two-level quantum system of a spin degree of freedom. An example of a spin qubit is the two-level quantum system of the spin of an electron confined in a quantum dot. Another example is a hole spin qubit. Furthermore, a group of electrons, for example two or three electrons, may be used to implement a spin qubit, such as an S-T0 singlet-triplet system of two electrons in a quantum double-dot.

The method of the present disclosure is applicable to any type of electrically controllable spin qubit implemented in a semiconductor heterostructure 12. Using an electron-based spin qubit involves bringing the electron spin into a known state. To this end, the state of the electron is initialized. In one aspect, a selected qubit is associated with the same electron throughout the performing of a quantum algorithm. In another aspect, a qubit implemented by a first electron may be initialized and, subsequently to an operation on the qubit, the qubit may be implemented by means of a second electron. In a further aspect, there are situations in which it is impossible to tell whether the qubit is implemented by the first electron or by the second electron, without compromising the performing of quantum algorithms. Likewise, the method of the present disclosure may be applied on any type of hole spin qubit.

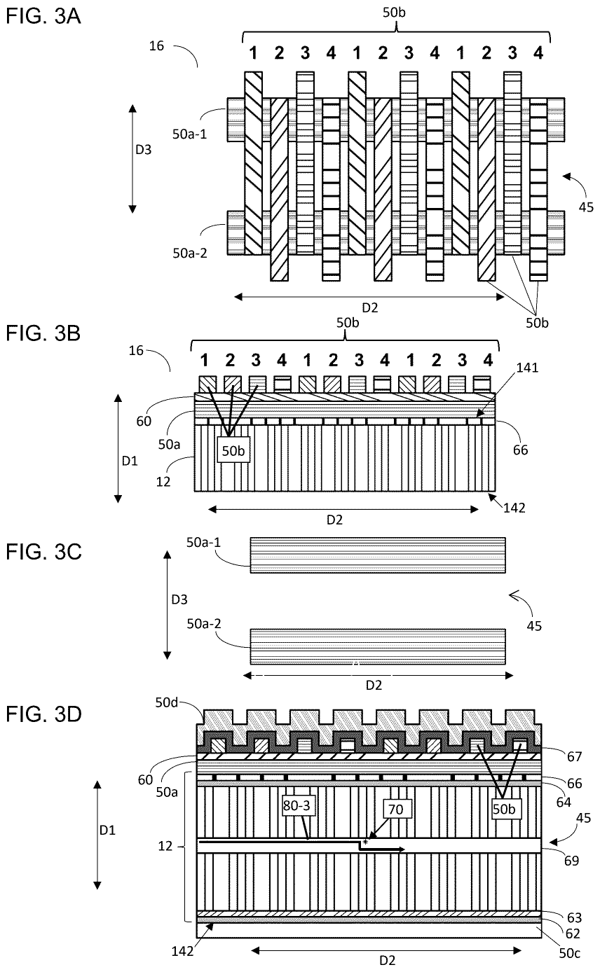

Using semiconductor materials to forma structure, e.g., a semiconductor heterostructure 12, for implementing the quantum processor facilitates manufacturing due to easy handling and low costs of the materials, such as in the case of silicon. There are established technologies for using silicon in computing hardware. A two-dimensional electron gas (2DEG) or a two-dimensional hole gas (2DHG) is confinable within the semiconductor heterostructure 12, formed from the semiconductor materials, in a quantum well 69 (see below and, e.g., FIG. 3D). The 2DEG or the 2DHG may further be confined based on electrical potentials. The electric potentials may be static electric potentials or non-static electric potentials. The electrical potentials may form at least one quantum dot, in which at least one electron or hole of the 2DEG or 2DHG is trappable or confinable. The spin of the trapped (confined) at least one electron or hole is usable to implement spin qubits. Moving the electrical potentials results in moving the at least one quantum dot. The moving of the at least one quantum dot enables moving the trapped (confined) at least one electron/hole as well as the qubits associated with the trapped (confined) at least one electrons/holes. Altering a strength of the electrical potentials alters the degree of confinement of the trapped (confined) at least one electron or hole.

The quantum processor may comprise a plurality of unit cells 26. A unit cell 26 of the plurality of unit cells comprises components that perform at least one action or operation on one or more qubits located in the unit cell 26. The at least one action on the one or more qubits includes: loading of the one or more qubits into the unit cell 26; unloading of the one or more qubits from the unit cell 26; moving (shuttling) the one or more qubits within the unit cell 26 or beyond the unit cell 26 (i.e., to another one of the unit cell 26 of the quantum processor); manipulating a quantum state of the one or more qubits; and readout of the quantum state of the one or more qubits. The manipulating of the one or more qubits may comprise manipulating a single qubit or manipulating two qubits. The manipulating of the single qubit comprises rotating the spins of the single qubit, e.g., for driving transitions between a plurality of spin states. The plurality of spin states may comprise, e.g., a spin-up state and a spin-down state. The manipulating of the two qubits may serve to implement a CPHASE gate, a CNOT gate, and/or a SWAP gate. The manipulating of the two qubits may further serve to implement a SQRT(SWAP) gate. Implementing a CNOT gate and one or more single-qubit gates, such as rotations or phase shifts, are sufficient to implement a quantum computer. The CNOT gate may be realized as a CPHASE gate in spin-qubit-based quantum computers.

In one aspect, several actions performed on the one or more qubits by the components of the unit cell 26 may be performed one after another as a sequence of actions. For example, two actions may be performed one after another. In another aspect, the several actions performed on the one or more qubits by the components of the unit cell 26 may be performed in parallel. For example, the two actions may be performed in parallel.

In one aspect, the several actions on the one or more qubits may be performed within a single one of the plurality of the unit cells 26 or across several ones of the plurality of unit cells 26.

In one aspect, the several actions may be performed as part of determining a gate fidelity (see below for more details). For example, the determining of the gate fidelity may comprise performing the sequence of actions on the one or more qubits.

In another aspect, the several actions may be performed as part of performing an algorithm. For example, the performing of the algorithm may comprise performing the sequence of actions on the one or more qubits.

The components are arranged within the unit cell 26. Some of the components are connected with each other. The components and the connections of the components thus form a layout or structure of the unit cell 26. Ones of the plurality of unit cells 26 may have substantially the same structure, in which the same components are arranged and connected with each other in substantially the same way. Other ones of the plurality of unit cells 26 may have differing structures, in which the components and/or the connections of the components differ.

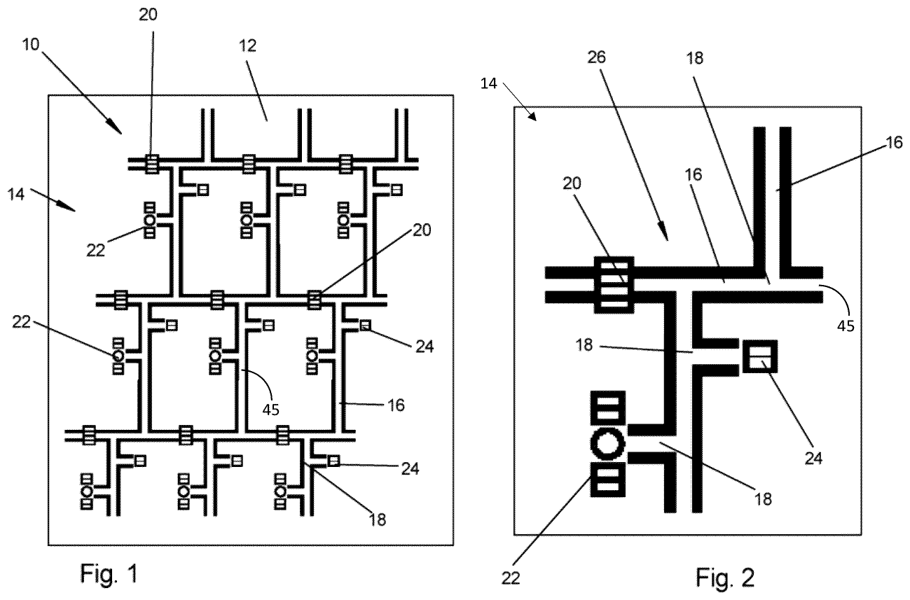

An aspect of the quantum processor is disclosed in international patent application no. WO 2021/052541 A1, the disclosure of which is incorporated herein by reference in its entirety. In this aspect, shown in FIGS. 1 and 2, the quantum processor 10 comprises the semiconductor heterostructure 12. The semiconductor heterostructure 12 comprises several layers of differing material composition. The semiconductor heterostructure 12 may be a Si/SiGe or GaAs/AlGaAs heterostructure, however, the use of other materials in which a two-dimensional electron gas (2DEG) or a two-dimensional hole gas (2DHG) can be formed, such as Si-MOS or Ge/SiGe, is possible. The semiconductor heterostructure may be undoped and/or strained. The semiconductor heterostructure 12 may serve as a substrate of the quantum processor 10. The semiconductor heterostructure 12 may comprise the 2DEG. The 2DEG or the 2DHG may be arranged or located in the quantum well 69 (see, e.g., FIG. 3D). The one or more qubits may be arranged in the quantum well 69. The one or more qubits may be arranged in the at least one quantum dot formed in the quantum well 69. The one or more qubits may be generated from the 2DEG.

In one aspect, the semiconductor heterostructure 12 may further comprise a silicon cap 64, on which a dielectric or insulating layer 66 is arranged (see FIG. 3D). The gate electrodes 50a, 50b, 50d may be arranged on top of the dielectric or insulating layer 66.

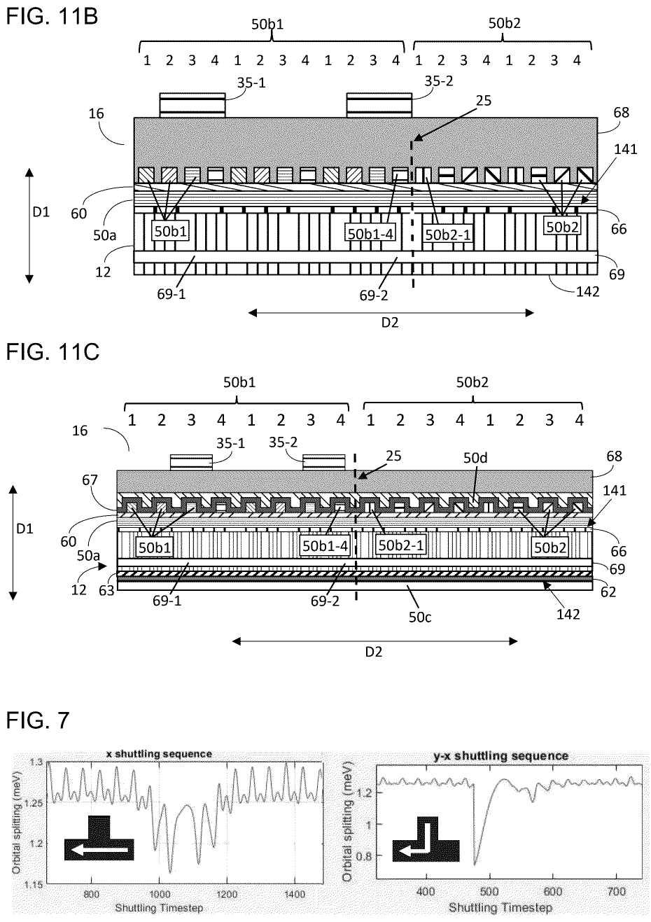

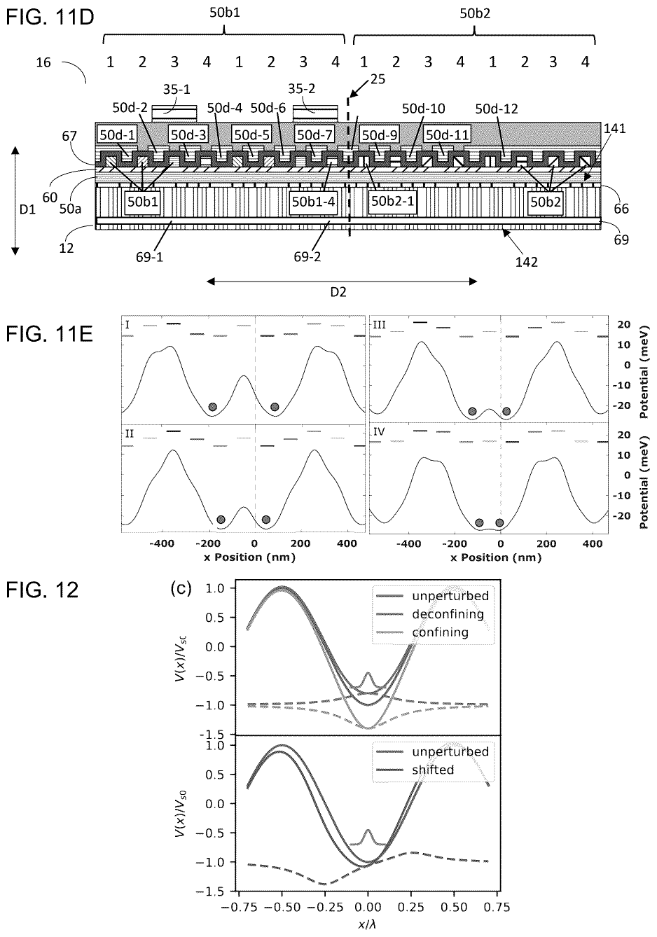

In a further aspect, the semiconductor heterostructure 12 may further comprise a layer of strained silicon 63 (see FIG. 3D). In yet a further aspect, the semiconductor heterostructure 12 may further comprise a layer of silicon dioxide 62 (see FIG. 3D or 11C).

In the aspect of the quantum processor 10 shown in FIGS. 1 and 2, the components 16, 18, 20, 22, 24 are provided on at least one surface 14 of the semiconductor heterostructure 12. As can be seen in FIG. 1, the shown aspect of the quantum processor 10 comprises one or more of each of the components 16, 18, 20, 22, 24. In another aspect, the quantum processor 10 may comprise one or more of only some of the component 16, 18, 20, 22, 24.

The quantum processor 10 shown in FIGS. 1 and 2 is a substantially two-dimensional device, as defined by the at least one surface 14. A third dimension of the quantum processor 10 is defined by a thickness of the semiconductor structure 12 and a thickness of the components 16, 18, 20, 22, 24.

The plurality of unit cells 26 of the quantum processor 10 comprises several of the unit cell 26 (shown in FIG. 2). In the aspect shown in FIG. 2, the unit cell 26 comprises the components 16, 18, 20, 22, 24. In another aspect of the disclosure, the unit cell 26 comprises merely some of the components 16, 18, 20, 22, 24. In yet a further aspect, the unit cell 26 may comprise more than one of at least one of the components 16, 18, 20, 22, 24.

The components 16, 18, 20, 22, 24 comprise a plurality of gate electrodes 50 (see, e.g., FIGS. 3A to 3D) arranged on at least one surface 14 of the semiconductor heterostructure 12. The plurality of gate electrodes 50 may be arranged to define within the quantum well 69 of the associated one of the components 16, 18, 20, 22, 24 at least one path 45 (see FIGS. 1, 2, 3A, 3C, 3D, 4A,, 4C,) along which the one or more qubits may be moved (shuttled).

In FIGS. 1 and 2, the at least one path 45 is shown to substantially be directed in two directions on the surface 14 that are substantially perpendicular to one another, resulting in structure of a plurality of paths 45 that is grid-like. The plurality of paths 45 connect the components 16, 18, 20, 22, 24.

The plurality of gate electrodes 50 may further be arranged to move (shuttle) the one or more qubits along the at least one path 45. The movement (shuttling) may occur in either one of the two directions (back and forth) along the at least one path 45. The plurality of gate electrodes 50 may further be arranged for performing the at least one action on the one or more qubits, performed by the components 16, 18, 20, 22, 24.

The plurality of gate electrodes 50 may be provided with voltages. The plurality of gate electrodes 50 may be made of metal. The plurality of gate electrodes 50 may be superconducting. The voltages may serve one or more purposes, such as defining the at least one path 45, moving (shuttling) the one or more qubits, and/or implementing the at least one action on the one or more qubits. The voltages may comprise DC (direct current) voltages and AC (alternating current) voltages. The voltages may comprise one or more stationary voltages and one or more non-stationary voltages. The voltages may be applied by means of DC lines, AC lines, and/or bias tees.

One or more of the components 16, 18, 20, 22, 24 may further comprise at least one magnet 35, such as a micromagnet (see FIGS. 11B-11D). The at least one micromagnet 35 may be placed on top of the component 16, 18, 20, 22, 24. The at least one micromagnet provides a magnetic field. The magnetic field may have a zero gradient or a non-zero gradient. The at least one magnet 35 may have a distance from the quantum well 69 of 150nm. The at least one magnet may have dimensions of 400 nm×200 nm×20 nm. The at least one magnet 35 may be arranged on a dielectric or insulating layer 68 (see FIGS. 11B-11D).

The dielectric or insulating layer 68 may be arranged on the conveyor gates 50b (see FIG. 11B) or on a top gate 50d (see FIGS. 11C and 11D and below).

An external magnetic field Bo splits the plurality of spin states (e.g., the spin-up state and the spin-down state) used as a computational basis for the one or more qubits into spin-dependent energy levels (Zeeman splitting). The external magnetic field Bo may be provided by an external magnet, e.g., an electromagnet (not shown), that is placed in the vicinity of the quantum processor 10. The quantum processor 10 may at least partially be placed in the external magnetic field provided by the external magnet.

The one or more components 16, 18, 20, 22, 24 may further comprise means for providing electromagnetic radiation, e.g., microwaves, for manipulating the quantum state of the one or more qubits, e.g., switching the spins of the one or more qubits between the plurality of spin states. The electromagnetic radiation may be provided by means of one or more of the gate electrodes 50b. The spins of the one or more qubits may thus be switched between, e.g., the spin-up and the spin-down state, or vice versa, by means of the electromagnetic radiation based on electron spin resonance (ESR). The frequency of the electromagnetic radiation may equal the energy difference of the separated energy levels. ESR provides a further way of manipulating the quantum state of the one or more qubits. The microwaves may have a frequency in the range of several hundred MHz to several hundred GHz. In one aspect, the frequency lies in the range of 9-10 GHz, but is not limited thereto.

Providing, e.g., by means of the at least one magnet 35, an inhomogeneous magnetic field i.e., having a non-zero gradient, enables manipulating the quantum state of the one or more qubits, e.g., rotating the spin of the qubit. The rotating enables driving transitions between the plurality of spin states by means of a displacement of the one or more qubits in the inhomogeneous magnetic field based on, e.g., an AC electric field. The AC electric field may be provided by means of one or more of the gate electrodes 50b. The AC electric field may be provided by means of one or more of the gate electrodes 50b This effect is called electric dipole spin resonance (EDSR). The displacement may make the one or more qubits oscillate between the plurality of spin states (e.g., the spin states forming the computational basis such as the spin-up state and the spin-down state). For example, the one or more qubits may oscillate such that the spin-up state can be switched to the spin-down state, and vice versa.

Alternatively, the EDSR may be achieved in one of the semiconductor heterostructure 12 in which spin-orbit coupling is present. The semiconductor heterostructure 12 may be made from semiconductor materials that provide the spin-orbit coupling.

The plurality of gate electrodes 50 may be provided as one or more of gate electrode assemblies 50a, 50b, 50c, 50d. The plurality of gate electrodes 50 may comprise one or more laterally positioning gate electrodes (also termed “screening gates”) 50a (see FIG. 3A) arranged to define and/or modify a lateral position of a trajectory 80 (see FIG. 5) in the quantum well 69 and/or at the at least one path 45 for moving (shuttling) the one or more qubits within the unit cell 26 or beyond the unit cell 26. The trajectory 80 may be a trajectory of one or more potential wells (further described below), in which the one or more qubits are arrangeable. The one or more potential wells may thus be one or more travelling potential wells. The trajectory 80 of the one or more potential wells may thus correspond to a trajectory of the one or more qubits arranged at the least one path 45. Thus, the lateral position of the trajectory 80 may correspond to a lateral position of the one or more potential wells and/or of the one or more qubits. Arranging the one or more qubits at the least one path 45 is to be understood to mean that the one or more qubits are arranged within the quantum well 69.

The plurality of gate electrodes 50 may further comprise one or more shuttling gate electrodes (also termed “conveyor gates” or “finger gates”) 50b (see FIG. 3A) arranged to move (shuttle) the one or more qubits along the at least one path 45 for moving (shuttling) the one or more qubits within the unit cell 26 or beyond the unit cell 26.

The plurality of gate electrodes 50 may further comprise at least one pitch-enhancing gate electrode (also termed “top gate”) 50d arranged to enable enhancing a pitch or spacing of the conveyor gates 50b.

The plurality of gate electrodes 50 may further comprise at least one vertically positioning gate electrode (also termed “back gate”) 50c arranged to define and/or modify a vertical position of the trajectory 80 (see FIG. 3D) in the quantum well 69 and/or at the at least one path 45 for moving (shuttling) the one or more qubits within the unit cell 26 or beyond the unit cell 26. The vertical position of the trajectory 80 may correspond to a vertical position of the one or more potential wells and/or of the one or more qubits.

The plurality of gate electrodes 50 may further comprise qubit-handling gate electrodes arranged for performing the at least one action on the one or more qubits. The qubit-handling electrodes include plunger gates and barrier gates. The plunger gates may be used to control the occupation of a quantum dot, to control a detuning in a double quantum dot, and/or to perform an exchange of two qubits. The barrier gates may be used to form a potential double-well and/or to control the tunnel barrier in a double quantum dot.

The plurality of gate electrodes 50 may be arranged on the at least one surface 14 of the semiconductor heterostructure 12. The plurality of gate electrodes 50 be may be arranged in layers that are separated by an insulating or dielectric layer 60 and/or the insulating or dielectric layers 66 (see FIGS. 3B and 3D). In one aspect, the layers may be arranged in a direction substantially perpendicular to the direction of the at least one path 45.

One or more of the insulating or dielectric layer 60, the insulating and dielectric layer 66, and/or the insulating or dielectric layer 67 may be planarized. A method of manufacturing the shuttling element 16 may comprise the step of planarizing one or more of the insulating or dielectric layer 60, the insulating and dielectric layer 66, and/or the insulating or dielectric layer 67. The insulating or dielectric layer 60 may be planarized during manufacturing before arranging the conveyor gates 50b on the insulating or dielectric layer 60. The planarizing facilitates using processes such as electron ray epitaxy, Deep UV, and/or spacer lithography. The planarizing reduces the thickness of one or more of the dielectric or insulating layers 60, 66, 67. For instance, the insulating or dielectric layers 66 and/or 60 may be planarized before manufacturing of the conveyor gates 50b to reduce the thickness of the insulating or dielectric layer 66 and/or 60, respectively. After planarization, the insulating or dielectric layers 66 and/or 60 are tightly placed on the semiconductor heterostructure 12. Planarizing the insulating or dielectric layers 66 and/or 60 results in the thickness of the insulating or dielectric layers 66 and/or 60 being reduced between the at least one path 45 and the conveyor gates 50b. In one aspect, the thickness of the insulating or dielectric layer 60 is required to cover a top surface and sides of the screening gates 50a.

The component 16 serves to move (shuttle) the one or more quantum dots in the semiconductor heterostructure 12 for moving (shuttling) the one or more qubits within the unit cell 26 or beyond the unit cell 26. The component 16 is also termed “shuttling lane”. Aspects of the shuttling lane 16 are disclosed in international patent application no. WO 2021/052531 A1, the disclosure of which is incorporated herein by reference in its entirety.

The component 18 provides a junction at which the one or more quantum dots may be diverted into at least one branch 45′ (at least one second one of the at least one path 45) that branches off of the at least one path 45 for moving (shuttling) the one or more qubits within the unit cell 26 or beyond the unit cell 26. The component 18 is also termed “T-junction”. The at least one path 45 and the at least one branch 45′ of the T-junction 18 are arranged substantially perpendicular to one another. In one aspect, the at least one path 45 and the at least one branch 45′ of the T-junction 18 may substantially form a T-shape. Aspects of the T-junction 16 is disclosed in international patent application no. WO 2021/052539 A1, the disclosure of which is incorporated herein by reference in its entirety.

The component 20 is provided for manipulating qubits in quantum dots. The component 20 is also termed “manipulation zone”. The manipulation zone 20 enables manipulating one or more current spin state of the one or more qubits. Any one qubit has a current spin state. In one aspect, the plurality of spin states may comprise the current spin state. In another aspect, the current spin state may be a linear combination of the plurality of spin states. During the manipulating, the one or more current spin states may be changed. Aspects of the manipulation zone 20 are disclosed in WO 2021/052537 A1, the disclosure of which is incorporated herein by reference in its entirety.

The component 22 serves to initialize the one or more spin states of the one or more qubits. When the one or more spin states have been initialized, any one of the one or more current spin states is equal to one of the plurality of spin states. After initialization, the one or more current spin states may remain unchanged during a relaxation time. The relaxation time describes transitions between the spin-up state and the spin-down state due to interactions with the environment, such as the lattice of the semiconductor heterostructure 12. The component 22 is also termed “initialization zone”. Aspects of the initialization zone 22 are disclosed in WO 2021/052538 A1, the disclosure of which is incorporated herein by reference in its entirety.

The component 24 serves to read out the one or more current spin states of the one or more qubits. When the one or more spin states have been read out, any one of the one or more current spin states prior to readout is known. The component 24 is also termed “readout zone”. Aspects of the readout zone 24 are disclosed in WO 2021/052536 A1, the disclosure of which is incorporated herein by reference in its entirety.

In one aspect of the disclosure, one component 22, 24 for initialization and readout comprises the initialization zone 22 and the readout zone 24.

The quantum processor 10 is operated to perform algorithms, such as quantum algorithms. The performing of the algorithms includes performing the sequence of actions on the one or more qubits, as explained above. The at least one action is performed by the components 16, 18, 20, 22, 24 of the unit cells 26.

The operating of the quantum processor 10 involves controlling the at least one action performed by the components 16, 18, 20, 22, 24. In one aspect of the disclosure, the at least one action is controlled by applying the voltages to the plurality of gate electrodes 50. The voltages may be set and/or adjusted to increase a fidelity F of the at least one action or of the sequence of actions. The fidelity F is a measure of how reliably the at least one action or the sequence of actions results in the outcome that is expected based on the design of the quantum processor 10 and on the voltages applied to the plurality of gate electrodes 50. To determine the fidelity F, the at least one action or the sequence of actions is repeated; subsequently the proportion of the repetitions is determined in which the actual outcome equals the expected outcome. The actual outcome includes the one or more current spin states that have been read out at the readout zone 24 after the at least one action or the sequence of actions. The expected outcome includes the one or more current spin states that are, based on known fidelities of the components 16, 18, 20, 22, 24 and/or the relaxation time of the one or more qubits, expected to be read out at the readout zone 24 after the at least one action or the sequence of actions.

For example, the at least one action may comprise the moving (shuttling) of the one or more qubits along the at least one path 45 of the shuttling lane 16. In this case, the fidelity F is a shuttling fidelity. The shuttling fidelity is understood to be a probability that the one or more current spin states of the one or more qubits are preserved during shuttling. The shuttling fidelity may be determined, for example, by repeatedly performing the sequence of actions: initialization of the one or more qubits, moving (shuttling) of the one or more qubits, and readout of the one or more qubits; followed by determining whether the initialized spin state of the one or more qubits are equal to the one or more current spin states after shuttling and prior to readout; and finally calculating the proportion of the repetitions in which the one or more current spin states were unaltered.

Another example is diverting the one or more qubits during the moving of the one or more qubits. When the one or more qubits are in proximity of the T-junction 18, the moving of the one or more qubits may include diverting the one or more qubits at the junction 28. The diverting means changing a direction along which the one or more qubits are moved. The T-junction 18 may be associated with a straight-shuttling fidelity F_{SS}. During straight shuttling, the one or more qubits do not change the direction along which the one or more qubits are moved (see description of FIG. 7 below). The straight shuttling fidelity similar to the above-described shuttling fidelity. However, the straight shuttling includes moving the one or more qubits past the junction 28. Furthermore, the T-junction 18 may be associated with a turning-off fidelity F_{TO}. During turning off, the one or more qubits change the direction along which the one or more qubits are moved (see description of FIG. 7 below). The turning off includes changing the direction, along which the one or more qubits are moved, at the junction 28.

As explained above, determining the shuttling fidelity F_{S} involves an initialization step and a readout step. In a manner analogous to the determination of the manipulation fidelity FM, the shuttling fidelity F_{S} may be determined by determining a fidelity F that is a combination, i.e., a product, of an initialization fidelity, a shuttling fidelity, and a readout fidelity, and by subsequently dividing the fidelity F by the initialization fidelity and the readout fidelity. Similarly, the straight-shuttling fidelity F_{SS} may be determined as a combined fidelity of the initialization fidelity, the straight-shuttling fidelity F_{SS}, and the readout fidelity, and by subsequently dividing the combined fidelity F by the initialization fidelity and the readout fidelity. Similarly, the turning-off fidelity F_{TO} may be determined as a combined fidelity of the initialization fidelity, the turning-off fidelity F_{TO}, and the readout fidelity, and by subsequently dividing the combined fidelity F by the initialization fidelity and the readout fidelity.

In yet a further example, the at least one action may comprise the moving (shuttling) of the one or more qubits along the at least one path 45 of the shuttling lane 16, e.g., to the manipulation 20, and the manipulating the quantum state of the one or more qubits in the manipulation zone 20. In this case, the fidelity F of performing the at least one action is a combination, i.e., the product, of a shuttling fidelity F_{S} and a manipulation fidelity F_{M}, i.e., F =F_{S}×F_{M}. The manipulation fidelity F_{M}, relating to the manipulation zone 20, may then be calculated by dividing the fidelity F by the shuttling fidelity. The manipulation fidelity F_{M} is understood to be a probability that the one or more current spin states of the one or more qubits are changed as expected during the manipulating. The shuttling fidelity F_{S} may be determined, for example, by repeatedly performing the sequence of actions: initialization of a qubit, moving (shuttling) of the qubit, and readout of the qubit; followed by determining whether the initialized spin state of the one or more qubits are equal to the one or more current spin states after shuttling and prior to readout; and finally calculating the proportion of the repetitions in which the one or more spin states were unaltered. The manipulation fidelity FM may be determined, for example, by repeatedly performing the sequence of actions: initialization of the one or more qubits, moving (shuttling) of the one or more qubits, manipulation of the one or more qubits, and readout of the one or more qubits; followed by determining whether the one or more initialized current spin states of the one or more qubits are changed as expected; calculating the proportion of the repetitions in which the one or more current spin state are changed as expected, dividing the result by the shuttling fidelity F_{S}.

The fidelity F may further be a gate fidelity. The gate fidelity F is a measure of how closely the outcome of a gate operation (i.e., the sequence of actions by means of the components 16, 18, 20, 22, 24 on the one or more qubits that are associated with a gate the quantum processor 10 is designed to implement) matches the expected, e.g., theoretical, outcome based on the design of the quantum processor 10 and the components 16, 18, 20 22, 24. The gate fidelity F may be determined by randomized benchmarking.

As an example, increasing the shuttling fidelity F of a single qubit along a shuttling lane 16 will be described. FIG. 3A shows an aspect of the shuttling lane 16. The shuttling lane 16 comprises the screening gates 50a and the conveyor gates 50b arranged on the at least one surface 14 of the semiconductor heterostructure 12. In the aspect shown in FIG. 3A, the at least one surface 14 comprises a top surface 141 of the semiconductor heterostructure 12. In the aspect shown in FIG. 3B, the top surface 141 may be a top surface of the dielectric or insulating layer 66 (further described below).

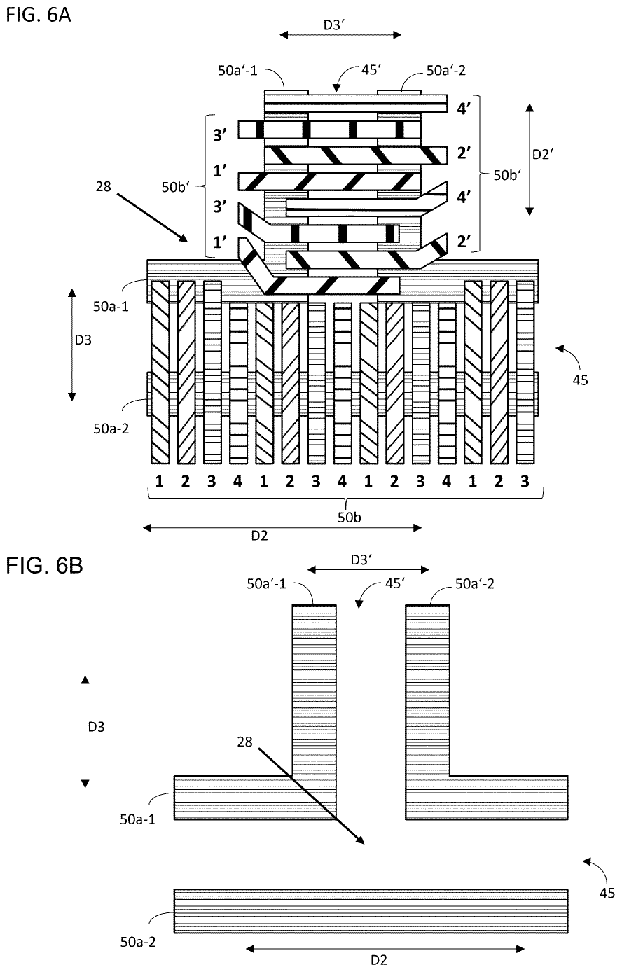

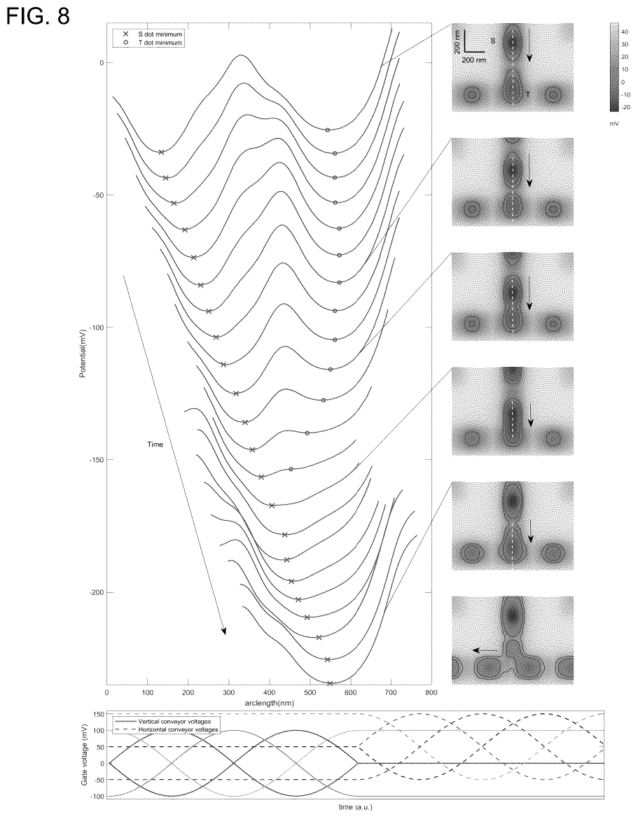

The screening gates 50a are arranged to extend on either side of the at least one path 45 as screening gates 50a-1 and 50a-2 (see also FIG. 3C). In one aspect, as shown in FIGS. 3A-3C, the screening gates 50a-1 and 50a-2 may extend continuously along the at least one path 45. In another aspect, as shown in FIG. 6A-6B, one of the screening gates 50a-1 and 50a-2 may be interrupted along the at least one path 45, e.g., where the branch 45′ branches off of the at least one path 45. The screening gates 50a-1 and 50a-2 may be spaced apart by approximately 200 nm. The screening gates 50a may be made from metal and may be manufactured by embedding the metal in the semiconductor heterostructure 12 or by local implantation of the semiconductor heterostructure 12. The screening gates 50a may be embedded in the dielectric or insulating layer 66 and/or in the dielectric or insulating layer 60.

The dielectric or insulating layer 66 and/or in the dielectric or insulating layer 60 may be structured in the lateral direction D3. In one aspect, the dielectric or insulating layer 66 and/or in the dielectric or insulating layer 60 may be provided as two separate portions (not shown), the separate portions enveloping the two screening gates 50a-1 and 50a-2, and the semiconductor heterostructure 12 extending into a space (not shown) between the two portions along the lateral (or transverse direction) D3. The semiconductor heterostructure 12 thus may form a ridge (not shown) in the space between the two portions of the dielectric or insulating layer 66 and/or in the dielectric or insulating layer 60.

The conveyor gates 50b are arranged to extend transversely across the at least one path 45 (as shown in FIG. 3A). For example, the conveyor gates 50b may extend in a lateral direction D3. The conveyor gates or finger gates 50b may be arranged along the at least one path 45.

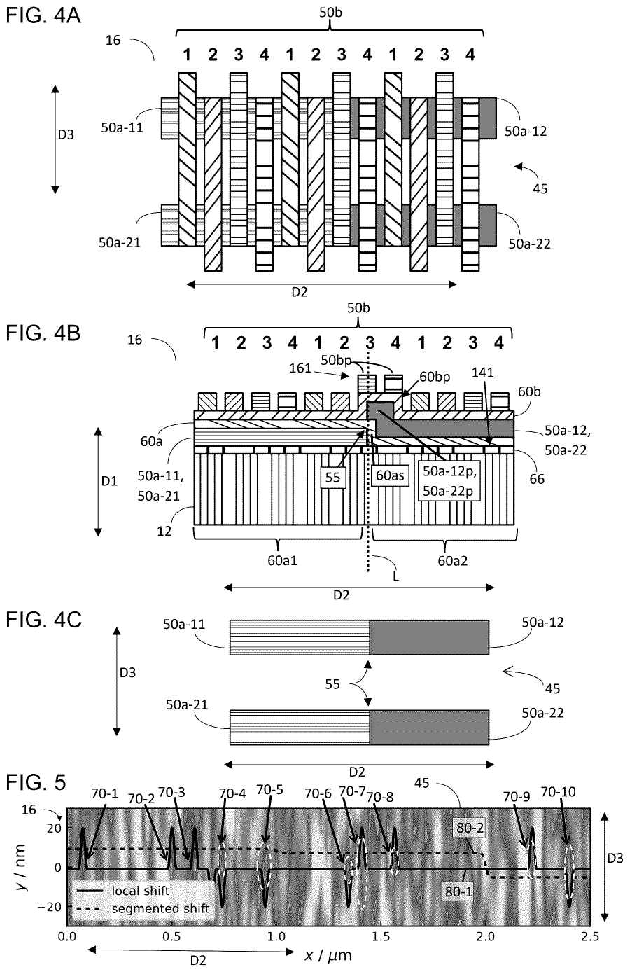

In the aspect shown in FIG. 3A, the conveyor gates 50b are provided in electrode subsets 50b-1, 50b-2, 50b-3, 50b-4 (indicated in FIG. 3A by indices 1, 2, 3, 4 above the conveyor gates of the corresponding electrode subset). The ones of the conveyor gates 50b that belong to one of the electrode subsets 50b-1, 50b-2, 50b-3, 50b-4 are marked with the same index at the top of FIGS. 3A, 3B, 4A, 4B, i.e., the index 1, 2, 3, or 4. The number of electrode subsets 50b-1, 50b-2, 50b-3, 50b-4 shown in FIG. 3A is four. However, the number of the electrode subsets of the conveyor gates 50b may differ from this example and be, e.g., three or five. Any number of the electrode subsets of the conveyor gates 50b may be chosen, as long as the one or more travelling potential wells for moving (shuttling) the qubit or the one or more qubits (see below) can be generated.

The one or more travelling potential wells provide the confinement to trap an electron or hole, the strength of which is sufficiently strong to overcome disorder during moving (shuttling) in the quantum well 69, and the height of which provide barriers between adjacent potential well to suppress tunnelling. The trapped one or more electrons or holes adiabatically follow a sufficiently slow translation of the potential. The disorder is due to one or more of defects at boundaries of the layers of the semiconductor heterostructure 12, defects within the layers of the heterostructure 12, and/or defects within the dielectric layers 60, 66 and/or 67. The defects at the boundaries of the layers of the semiconductor heterostructure 12 include charge defects at interfaces between layers made from semiconductor materials and the dielectric or insulating layers 60 and/or 66. These charge defects are randomly distributed, e.g., at the interfaces. A density of the charge defects was set to 5E10/cm². Transitions to excited orbital states of the electron confined in the one or more travelling potential wells are caused by the disorder. In a moving frame of the one or more travelling potential wells, the disorder that quasi-statically fluctuates turns into dynamic noise that couples the orbital levels. Setting the shuttling speed is set to v=10 m/s results in a reduced orbital excitation rate and a below-threshold phase error.

As another example, increasing the manipulation fidelity FM of one or more qubits, e.g., the single qubit or the two qubits, at the manipulation zone 20 will be described. FIG. 11A shows an aspect of the manipulation zone 20. The manipulation zone 20 comprises the screening gates 50a and the conveyor gates 50b arranged on the at least one surface 14 of the semiconductor heterostructure 12. In the aspect shown in FIG. 11A, the at least one surface 14 comprises a top surface 141 of the semiconductor heterostructure 12. In the aspect shown in FIG. 11B, the top surface 141 may be a top surface of dielectric or insulating layer 66 (further described below).

The screening gates 50a are arranged to extend on either side of a first path 451 and a second path 452 as screening gates 50a-1 and 50a-2 (see also FIG. 11A). In one aspect, as shown in FIGS. 11A-11C, the screening gates 50a-1 and 50a-2 may extend continuously along the at least one path 45. In another aspect, the screening gates 50a-1 and 50a-2 may be interrupted. The screening gates 50a-1 and 50a-2 may be spaced apart by approximately 200 nm, e.g., 190 nm, 195 nm, 200 nm, 205 nm, 210 nm, or value lying in between those mentioned or beyond 190 nm or 210 nm. The screening gates 50a may be made from metal and may be manufactured by embedding the metal in the semiconductor heterostructure 12 or by local implantation of the semiconductor heterostructure 12. The screening gates 50a may be embedded in the dielectric or insulating layer 66 and/or in the dielectric or insulating layer 60.

The dielectric or insulating layer 66 and/or in the dielectric or insulating layer 60 may be structured in the lateral direction D3. In one aspect, the dielectric or insulating layer 66 and/or in the dielectric or insulating layer 60 may be provided as two separate portions (not shown), the separate portions enveloping the two screening gates 50a-1 and 50a-2, and the semiconductor heterostructure 12 extending into a space (not shown) between the two portions along the lateral (or transverse direction) D3. The semiconductor heterostructure 12 thus may form a ridge (not shown) in the space between the two portions of the dielectric or insulating layer 66 and/or in the dielectric or insulating layer 60.

The conveyor gates 50b may extend transversely across the first path 451 and/or the second path 452 (as shown in FIG. 11A). For example, the conveyor gates 50b may extend in a lateral direction D3. The conveyor gates or finger gates 50b are arranged along the at least one path 45.

In the aspect shown in FIG. 11A, the conveyor gates 50b have a first conveyor gate assembly 50b1 and a second conveyor gate assembly 50b2. In FIGS. 11A-D, the first conveyor gate assembly 50b1 and second conveyor gate assembly 50b2 are indicated by the braces at the top of the drawings. In addition, three electrodes belonging to the first conveyor gate assembly 50b1 and three electrodes belonging to the second conveyor gate assembly 50b2 are indicated in FIGS. 11A-D for the sake of clarity. The first conveyor gate assembly 50b1 and/or the second conveyor gate assembly 50b2 is arranged to extend transversely across at least part of the first path 451 and/or the second path 452, respectively. The first conveyor gate assembly 50b1 and the second conveyor gate assembly 50b2 are arranged at an interface 25 such that the first path 451 and the second path 452 meet at the interface 25 (see FIGS. 11A and 11B).

The first path 451 and the second path 452 meet at the interface 25 such that a first qubit, trapped in first quantum dot and shuttled along the first path 451 to the interface 25, and a second qubit, trapped in a second quantum dot and shuttled along the second path 452, can undergo at least one two-qubit action (or operation) at the interface 25. The one or more potential wells may comprise one or more first potential wells. The first qubit may be shuttled (moved) along the first path 451 by the one or more first travelling potential wells. The one or more first travelling potential wells may be generated by applying the voltages to the first conveyor gate assembly 50b1. Likewise, the one or more potential wells may comprise one or more second potential wells. The second qubit may be shuttled (moved) along the second path 452 by the one or more second travelling potential wells. The one or more second travelling potential wells may be generated by applying the voltages to the second conveyor gate assembly 50b2.

The at least one two-qubit action (or operation) at the interface 25 are enabled by forming at the interface ones of the one or more potential wells that are stationary (“one or more stationary potential wells”). The one or more stationary potential wells may comprise at least one first stationary potential well and at least one second stationary potential well.

The at least one first stationary potential well may be arranged at the interface 25. For instance, the at least one first stationary potential well may be adjacent to the interface. The at least one first stationary potential well may be generated by the first conveyor gate assembly 50b1. Likewise, the at least one second stationary potential well may be arranged at the interface 25. For instance, the at least one second stationary potential well may be adjacent to the interface. The at least one second stationary potential well may be generated by the second conveyor gate assembly 50b2.

The first qubit may be trapped in the at least one first stationary potential well. Likewise, the second qubit may be trapped in the at least one second stationary potential well. When the at least one first stationary potential well and the at least one second stationary potential are arranged at the interface 25, the first qubit trapped in the least one first stationary potential well and the second qubit trapped in the at least one second potential well may undergo the at least one two-qubit action (or two-qubit operation).

For example, at the interface 25 a potential barrier may be formed by means of the first conveyor gate assembly 50b1 and the second conveyor gate assembly 50b2 between the at least one first stationary potential well and the at least one second stationary potential well. For example, the potential barrier may be formed by an electrode subset 50b1-4 (described below) of the first conveyor gate assembly 50b1 and an electrode subset 50b2-1 (described below) of the second conveyor gate assembly 50b2.

A lowering/raising of the potential barrier may increase/decrease a tunnel coupling across the potential barrier (also referred to as “tunnel barrier”). In one aspect, the height of the potential barrier may be adjusted by pulsing, e.g., by non-adiabatic pulsing. The confinement in the at least one first stationary potential well and in the at least one second stationary potential well may or may not be different relative to one another, which is referred to as a detuning. The detuning may be zero or non-zero. The detuning may be generated by means of the first conveyor gate assembly 50b1 and the second conveyor gate assembly 50b2. For example, the detuning may be generated by an electrode subset 50b1-3 (described below) of the first conveyor gate assembly 50b1 and an electrode subset 50b2-2 (described below) of the second conveyor gate assembly 50b2.

The tunnel coupling and the detuning determine an exchange coupling J between the first qubit trapped in the first stationary potential well and the second qubit trapped in the second stationary potential well. The exchange coupling J enables the first qubit and/or the second qubit to tunnel through the potential barrier into the at least one first stationary well or the at least one second stationary potential well.

The first conveyor gate assembly 50b1 has electrode subsets 50b1-1, 50b1-2, 50b1-3, As an example, increasing the manipulation fidelity FM of one or more qubits, e.g., the single qubit or the two qubits, at the manipulation zone 20 will be described. FIG. 11A shows an aspect of the manipulation zone 20. The manipulation zone 20 comprises the screening gates 50a and the conveyor gates 50b arranged on the at least one surface 14 of the semiconductor heterostructure 12. In the aspect shown in FIG. 11A, the at least one surface 14 comprises a top surface 141 of the semiconductor heterostructure 12. In the aspect shown in FIG. 11B, the top surface 141 may be a top surface of dielectric or insulating layer 66 (further described below).

The screening gates 50a are arranged to extend on either side of a first path 451 and a second path 452 as screening gates 50a-1 and 50a-2 (see also FIG. 123A). In one aspect, as shown in FIGS. 11A-3C, the screening gates 50a-1 and 50a-2 may extend continuously along the at least one path 45. In another aspect, the screening gates 50a-1 and 50a-2 may be interrupted. The screening gates 50a-1 and 50a-2 may be spaced apart by approximately 200nm. The screening gates 50a may be made from metal and may be manufactured by embedding the metal in the semiconductor heterostructure 12 or by local implantation of the semiconductor heterostructure 12. The screening gates 50a may be embedded in the dielectric or insulating layer 66 and/or in the dielectric or insulating layer 60.

The dielectric or insulating layer 66 and/or in the dielectric or insulating layer 60 may be structured in the lateral direction D3. In one aspect, the dielectric or insulating layer 66 and/or in the dielectric or insulating layer 60 may be provided as two separate portions (not shown), the separate portions enveloping the two screening gates 50a-1 and 50a-2, and the semiconductor heterostructure 12 extending into a space (not shown) between the two portions along the lateral (or transverse direction) D3. The semiconductor heterostructure 12 thus may form a ridge (not shown) in the space between the two portions of the dielectric or insulating layer 66 and/or in the dielectric or insulating layer 60.

The conveyor gates 50b may extend transversely across the first path 451 and/or the second path 452 (as shown in FIG. 11A). For example, the conveyor gates 50b may extend in a lateral direction D3. The conveyor gates or finger gates 50b are arranged along the at least one path 45.

In the aspect shown in FIG. 11A, the conveyor gates 50b have a first conveyor gate assembly 50b1 and a second conveyor gate assembly 50b2. In FIGS. 11A-D, the first conveyor gate assembly 50b1 and second conveyor gate assembly 50b2 are indicated by the braces at the top of the drawings. In addition, three electrodes belonging to the first conveyor gate assembly 50b1 and three electrodes belonging to the second conveyor gate assembly 50b2 are indicated in FIGS. 11A-D for the sake of clarity. The first conveyor gate assembly 50b1 and/or the second conveyor gate assembly 50b2 is arranged to extend transversely across at least part of the first path 451 and/or the second path 452, respectively. The first conveyor gate assembly 50b1 and the second conveyor gate assembly 50b2 are arranged at an interface 25 such that the first path 451 and the second path 452 meet at the interface 25 (see FIGS. 11A and 11B).

The first path 451 and the second path 452 meet at the interface 25 such that a first qubit, trapped in first quantum dot and shuttled along the first path 451 to the interface 25, and a second qubit, trapped in a second quantum dot and shuttled along the second path 452, can undergo at least one two-qubit action (or operation) at the interface 25. The one or more potential wells may comprise one or more first potential wells. The first qubit may be shuttled (moved) along the first path 451 by the one or more first travelling potential wells. The one or more first travelling potential wells may be generated by applying the voltages to the first conveyor gate assembly 50b1. Likewise, the one or more potential wells may comprise one or more second potential wells. The second qubit may be shuttled (moved) along the second path 452 by the one or more second travelling potential wells. The one or more second travelling potential wells may be generated by applying the voltages to the second conveyor gate assembly 50b2.

The at least one two-qubit action (or operation) at the interface 25 are enabled by forming at the interface ones of the one or more potential wells that are stationary (“one or more stationary potential wells”). The one or more stationary potential wells may comprise at least one first stationary potential well and at least one second stationary potential well.

The at least one first stationary potential well may be arranged at the interface 25. For instance, the at least one first stationary potential well may be adjacent to the interface. The at least one first stationary potential well may be generated by the first conveyor gate assembly 50b1. Likewise, the at least one second stationary potential well may be arranged at the interface 25. For instance, the at least one second stationary potential well may be adjacent to the interface. The at least one second stationary potential well may be generated by the second conveyor gate assembly 50b2.

The first qubit may be trapped in the at least one first stationary potential well. Likewise, the second qubit may be trapped in the at least one second stationary potential well. When the at least one first stationary potential well and the at least one second stationary potential are arranged at the interface 25, the first qubit trapped in the least one first stationary potential well and the second qubit trapped in the at least one second potential well may undergo the at least one two-qubit action (or two-qubit operation).

For example, at the interface 25 a potential barrier may be formed by means of the first conveyor gate assembly 50b1 and the second conveyor gate assembly 50b2 between the at least one first stationary potential well and the at least one second stationary potential well. For example, the potential barrier may be formed by an electrode subset 50b1-4 (described below) of the first conveyor gate assembly 50b1 and an electrode subset 50b2-1 (described below) of the second conveyor gate assembly 50b2.

A lowering/raising of the potential barrier may increase/decrease a tunnel coupling across the potential barrier (also referred to as “tunnel barrier”). In one aspect, the height of the potential barrier may be adjusted by pulsing, e.g., by non-adiabatic pulsing. The confinement in the at least one first stationary potential well and in the at least one second stationary potential well may or may not be different relative to one another, which is referred to as a detuning. The detuning may be zero or non-zero. The detuning may be generated by means of the first conveyor gate assembly 50b1 and the second conveyor gate assembly 50b2. For example, the detuning may be generated by an electrode subset 50b1-3 (described below) of the first conveyor gate assembly 50b1 and an electrode subset 50b2-2 (described below) of the second conveyor gate assembly 50b2.

The tunnel coupling and the detuning determine an exchange coupling J between the first qubit trapped in the first stationary potential well and the second qubit trapped in the second stationary potential well. The exchange coupling J enables the first qubit and/or the second qubit to tunnel through the potential barrier into the at least one first stationary well or the at least one second stationary potential well.

The first conveyor gate assembly 50b1 has electrode subsets 50b1-1, 50b1-2, 50b1-3, 50b1-4 (indicated in FIGS. 11A-D by indices 1, 2, 3, 4 above the conveyor gates of the corresponding electrode subset). The ones of the conveyor gates 50b that belong to one of the electrode subsets 50b1-1, 50b1-2, 50b1-3, 50b1-4 are marked with the same index at the top of FIGS. 11A-11D, i.e., the index 1, 2, 3, or 4. The number of electrode subsets 50b1-1, 50b1-2, 50b1-3, 50b1-4 shown in FIG. 11A is four. Likewise, the second conveyor gate assembly 50b2 has electrode subsets 50b2-1, 50b2-2, 50b2-3, 50b2-4 (indicated in FIG. 11A-D by indices 1, 2, 3, 4 above the conveyor gates of the corresponding subset). The ones of the conveyor gates 50b that belong to one of the electrode subsets 50b2-1, 50b2-2, 50b2-3, 50b2-4 are marked with the same index at the top of FIGS. 11A-11D, i.e., the index 1, 2, 3, or 4. As shown in FIGS. 11A-11D, the interface 25 is located at one electrode of the electrode subset 50b1-4 of the first conveyor gate assembly 50b1 and at one electrode of the electrode subset 50b2-1 of the second conveyor gate assembly 50b2. The number of electrode subsets 50b2-1, 50b2-2, 50b2-3, 50b2-4 shown in FIG. 11A is four. However, the number of the electrode subsets of the first conveyor gate assembly 50b1 and/or the second conveyor gate assembly 50b2 may differ from this example and be, e.g., three or five. Any number of the electrode subsets of the conveyor gates 50b may be chosen, as long as the one or more travelling potential wells for moving (shuttling) a qubit (see below) can be generated. 50b1-4 (indicated in FIGS. 11A-D by indices 1, 2, 3, 4 above the conveyor gates of the corresponding electrode subset). The ones of the conveyor gates 50b that belong to one of the electrode subsets 50b1-1, 50b1-2, 50b1-3, 50b1-4 are marked with the same index at the top of FIGS. 11A-11D, i.e., the index 1, 2, 3, or 4. The number of electrode subsets 50b1-1, 50b1-2, 50b1-3, 50b1-4 shown in FIG. 11A is four. Likewise, the second conveyor gate assembly 50b2 has electrode subsets 50b2-1, 50b2-2, 50b2-3, 50b2-4 (indicated in FIG. 11A-D by indices 1, 2, 3, 4 above the conveyor gates of the corresponding subset). The ones of the conveyor gates 50b that belong to one of the electrode subsets 50b2-1, 50b2-2, 50b2-3, 50b2-4 are marked with the same index at the top of FIGS. 11A-11D, i.e., the index 1, 2, 3, or 4. As shown in FIGS. 11A-11D, the interface 25 is located at one electrode of the electrode subset 50b1-4 of the first conveyor gate assembly 50b1 and at one electrode of the electrode subset 50b2-1 of the second conveyor gate assembly 50b2. The number of electrode subsets 50b2-1, 50b2-2, 50b2-3, 50b2-4 shown in FIG. 11A is four. However, the number of the electrode subsets of the first conveyor gate assembly 50b1 and/or the second conveyor gate assembly 50b2 may differ from this example and be, e.g., three or five. Any number of the electrode subsets of the conveyor gates 50b may be chosen, as long as the one or more travelling potential wells for moving (shuttling) a qubit (see below) can be generated, as explained above with reference to the shuttling lane 16.

In one aspect, the conveyor gates 50b may be arranged at the at least one path 45 in a manner, in which juxtaposed ones of the conveyor gates 50b extend differently far in the lateral (or transverse) direction D3 (as shown in FIG. 3A). In another aspect the conveyor gates 50b may extend equally far in the lateral (or transverse direction) D3.

The conveyor gates 50b may be arranged in a substantially equidistant manner with a substantially constant conveyor gate spacing between any two neighboring conveyor gates 50b. If a conveyor gate width, i.e., an extension of the conveyor gates 50b in the longitudinal direction D3, of the conveyor gates 50b is substantially constant, a conveyor gate pitch, which is the sum of the conveyor gate spacing and the conveyor gate width, is substantially constant. In one aspect of the disclosure, the conveyor gate pitch may be approximately 80 nm. The conveyor gates 50b may be arranged in a periodic manner. In one aspect, the conveyor gates 50b of any one of the electrode subsets 50b-1, 50b-2, 50b-3, 50b-4 may be arranged in a substantially equidistant manner from each other based on a spatial period of the periodically arranged conveyor gates. In another aspect, any two conveyor gates 50b belonging to any selected one of the electrode subsets 50b-1, 50b-2, 50b-3, 50b-4 have one conveyor gate of each of the other non-selected ones of the electrode subsets arranged therebetween. The periodical arrangement of the conveyor gates 50b facilitates industrial manufacturing of the shuttling path 16.

The conveyor gates 50b belonging to one of the four electrode subsets 50b-1, 50b-2, 50b-3, 50b-4, shown in FIG. 3A, are electrically connected to each other by an electrical connection (not shown). The element gates of any selected electrode subset from the electrode subsets 50b-1, 50b-2, 50b-3, 50b-4 are electrically disconnected from (or not electrically connected to) the element gates of the corresponding non-selected electrode subsets. The electrical connection may be provided by a metal strip arranged parallel to the screening gates 50a. The electrode subsets of the conveyor gates 50b with indices 1 and 3 may have the electrical connection on one side of the at least one path 45 (above the at least one path 45 as seen in FIG. 3A). The electrode subsets of the conveyor gates 50b with indices 2 and 4 may have the electrical connection on the other side of the at least one path 45 (below the at least one path 45 as seen in FIG. 3A). In one aspect of the disclosure, the electrode subsets 50b-1, 50b-2, 50b-3, 50b-4 may be arranged at different levels in the stacking direction D1. For example, the metal strip connecting the conveyor gates of the electrode subset 50b-1 may be arranged on one side of the at least one path 45 at a higher level in the stacking direction D1 than the metal strip connecting the conveyor gates of the electrode subset 50b-3; and the metal strip connecting the conveyor gates of the electrode subset 50b-2 may be arranged on the other side of the at least one path 45 at a higher level in the stacking direction D1 than the metal strip connecting the conveyor gates of the electrode subset 50b-4. The electrode subsets 50b-1, 50b-2, 50b-3, 50b-4 may each be arranged at the level at which the corresponding metal strip is arranged. In another aspect, the metal strips may be all arranged on one side of the at least one path 45. In a further aspect, ones of the metal strips connecting the conveyor gates of the electrode subsets 50b-1, 50b-2, 50b-3, 50b-4 may be electrically connected to the conveyor gates of the corresponding electrode subset by vias; and the conveyor gates of the electrode subsets 50b-1, 50b-2, 50b-3, 50b-4 may be arranged at substantially one level in the stacking direction D1.

Likewise, the conveyor gates belonging to any one of the electrode subsets 50b1-1, 50b1-2, 50b1-3, 50b1-4, 50b2-1, 50b2-2, 50b2-3, 50b2-4, shown in FIG. 11A, are electrically connected to each other by an electrical connection (not shown). The conveyor gates of any selected electrode subset from the electrode subsets 50b1-1, 50b1-2, 50b1-3, 50b1-4, 50b2-1, 50b2-2, 50b2-3, 50b2-4 are electrically disconnected from (or not electrically connected to) the conveyor gates of the other ones (i.e., the corresponding non-selected ones) of the electrode subsets 50b1-1, 50b1-2, 50b1-3, 50b1-4, 50b2-1, 50b2-2, 50b2-3, 50b2-4.

The electrical connection may be provided by a metal strip arranged parallel to the screening gates 50a. The electrode subsets of the conveyor gates 50b1 and/or 50b2 with indices 1 and 3 may have the electrical connection on one side of the at least one path 45 (above the at least one path 45 as seen in FIG. 11A). The electrode subsets of the conveyor gates 50b with indices 2 and 4 may have the electrical connection on the other side of the at least one path 45 (below the at least one path 45 as seen in FIG. 11A). In one aspect of the disclosure, the electrode subsets 50b-1, 50b-2, 50b-3, 50b-4 may be arranged at different levels in the stacking direction D1. For example, the metal strip connecting the conveyor gates of the electrode subset 50b-1 may be arranged on one side of the at least one path 45 at a higher level in the stacking direction D1 than the metal strip connecting the conveyor gates of the electrode subset 50b-3; and the metal strip connecting the conveyor gates of the electrode subset 50b-2 may be arranged on the other side of the at least one path 45 at a higher level in the stacking direction D1 than the metal strip connecting the conveyor gates of the electrode subset 50b-4. The electrode subsets 50b-1, 50b-2, 50b-3, 50b-4 may each be arranged at the level at which the corresponding metal strip is arranged. In another aspect, the metal strips may be all arranged on one side of the at least one path 45. In a further aspect, ones of the metal strips connecting the conveyor gates of the electrode subsets 50b-1, 50b-2, 50b-3, 50b-4 may be electrically connected to the conveyor gates of the corresponding electrode subset by vias; and the conveyor gates of the electrode subsets 50b-1, 50b-2, 50b-3, 50b-4 may be arranged at substantially one level in the stacking direction D1.

The electrical connection of the element gates of any one of the electrode subsets 50b-1, 50b-2, 50b-3, 50b-4 or 50b1-1, 50b1-2, 50b1-3, 50b1-4, 50b2-1, 50b2-2, 50b2-3, 50b2-4 enables providing a single voltage to the corresponding electrode subset. In other words, the number of voltage signals applied to the conveyor gates 50b is given by the number of electrode subsets chosen. As a result, the number voltage signals applied to screening gates 50a and the conveyor gates 50b is independent of a length of the shuttling element 16. In the example shown in FIGS. 3A and 3B, the number of electrode subsets is four. However, the number may be smaller or larger than four. For example, using three electrode subsets may achieve moving the one or more qubits by means of the travelling potential well.

The at least one magnet 35 provides a magnetic field (not shown). The magnetic field may be an inhomogeneous magnetic field. The magnetic field of the magnetic field provided by the at least one magnet 35 may have a non-zero magnetic field strength at the quantum well 69. The magnetic field may have a longitudinal component of non-zero longitudinal magnetic field strength at the quantum well 69 along a shuttling direction (or longitudinal direction) D2. The magnetic field may have a transverse component of non-zero transverse magnetic field strength at the quantum well 69 along the lateral (or transverse) direction D3.

Furthermore, the magnetic field of the at least one magnet 35 may have a transverse component of non-zero transverse magnetic field strength and transverse to the external magnetic field Bo. This transverse component of the magnetic field may have a gradient in the shuttling direction D2. In addition or alternatively, the magnetic field of the at least one magnet 35 may have a parallel component of non-zero parallel magnetic field strength and parallel to the external magnetic field Bo. This parallel component of the magnetic field may have a gradient in the shuttling direction D2.

This enables the magnetic field acting on the one or more qubits, when the one or more qubits are trapped in a potential well in the quantum well 69 where the magnetic field strength is non-zero. With the inhomogeneous magnetic field of the at least one magnet 35, the EDSR (see above) may be used to rotate the one or more spins of the one or more qubits.

As shown FIGS. 11A-D, the at least one magnet 35 may comprise a first magnet 35-1 and a second magnet 35-2. An example of the first magnet 35-1 is a first micromagnet. An example of the second magnet 35-2 is a second micromagnet.

The first magnet 35-1 may be arranged at the first conveyor gate assembly 50b1. The first magnet 35-1 may be arranged at a distance from the interface 25. A first magnetic field of the first magnet 39-1, which may be inhomogeneous, has a first magnetic field strength (having a longitudinal component and/or a transverse component, as described above) that has a non-zero value at a first portion 69-1 of the quantum well 69. In one aspect, the first magnetic field strength substantially vanishes at the interface 25.

The second magnet 35-2 may arranged at the first conveyor gate assembly 50b1. The second magnet 35-2 may be arranged in a vicinity of the interface 25. In one aspect, the second magnet 35-2 may be arranged at the first conveyor gate assembly 50b1 and the second conveyor gate assembly 50b2. In other words, the second magnet 35-2 may extend across the interface 25 in the shuttling direction (or longitudinal direction) D2.

A second magnetic field of the second magnet 39-2, which may be inhomogeneous, has a second magnetic field strength (having a longitudinal component and/or a transverse component, as described above) that has a non-zero value at a second portion 69-2 of the quantum well 69. The second portion 69-2 may be located in the vicinity of the interface 25. In one aspect, the second portion 69-2 of the quantum well 69 may be located on both sides of the interface 25 along the shuttling direction (or longitudinal direction) D2. The second magnetic field strength may have a non-zero value at the interface 25.

In another aspect of the disclosure, the manipulation zone 20 may comprise solely the first magnet 35-1 or solely the second magnet 35-2.

In a further aspect of the disclosure, the shuttling path 16 and/or the manipulation zone 20 may comprise the top gate 50d (see FIGS. 3D, 11C, and 11D). The top gate 50d may extend in the lateral (transverse) direction D3. The top gate may extend in the shuttling direction (or longitudinal direction) D2. The top gate 50d may cover at least part of the first path 451 and/or the second path 452. In one aspect, at least in the lateral (transverse) direction D3, the top gate 50d completely covers the first path 451 and/or the second path 452.

In yet another aspect of the disclosure, the top gate electrode 50d may be arranged above of the conveyor gates 50b with a dielectric or insulating layer 67 arranged therebetween. The dielectric or insulating layer 67 may be partially arranged on the dielectric or insulating layer 60 (see FIGS. 3D, 11C, and 11D). Portions of the dielectric or insulating layer 67, which are arranged between the conveyor gates 50b, may be arranged on the dielectric or insulating layer 60. The dielectric or insulating layer 67 may be structured, e.g., segmented or profiled, in the shuttling direction D2 (see FIGS. 3D, 11C, and 11D). The dielectric or insulating layer 67 may be structured, e.g., segmented or profiled, in the shuttling direction D2 (see FIGS. 3D and 11D). The dielectric or insulating layer 67 insulates the conveyor gates 50b that belong to different ones of the subsets 50b-1, 50b-2, 50b-3, 50b-4 from each other. In one aspect of the disclosure, the dielectric or insulating layers 60 and 67 are a single dielectric or insulating layer 60, 67, in which the conveyor gates 50b are embedded.

A constant voltage may be applied to the top gate 50d. In a further aspect, the voltage applied to the top gate 50d may be modified for the one or more actions on the one or more qubits. For example, the voltage applied to the top gate 50d may be modified for shuttling the one or more qubits, for initializing the one or more qubits, for reading out of the one or more qubits, for manipulating the one or more qubits. In another example, the voltage applied to the top gate 50d may be modified according to sequence of actions on the one or more qubits, for instance as part of performing an algorithm. In yet a further aspect, the voltage applied to the top gate 50d may be modified periodically or non-periodically. The periodically modifying and/or the non-periodically modifying of the voltage applied to the top gate 50d may depend on the action performed on the one or more qubits. The periodically modifying of the voltage applied to the top gate 50d includes adding a square wave, a sawtooth wave, a superposition of sine waves. The periodically modifying of the voltage applied to the top gate 50d includes adding a stepwise increment to the voltage applied to the top gate 50d. The stepwise increment may depend on the one or more actions performed on the one or more qubits.

In one aspect, the top gate may have a planar top surface (not shown). In another aspect of the disclosure, the top gate 50d may be structured. An example of the structured top gate 50d is a segmented top gate 50d. Another example of the structured top gate 50d is a top gate with a surface profile (or profiled top gate), as shown in FIG. 3D or 11D. The structured top gate 50d may in one aspect be a segmented and profiled top gate. As shown in FIGS. 3D and 11D, the top gate 50d may be structured, e.g., segmented and/or profiled, along the shuttling direction (or longitudinal direction) D2. Additionally or alternatively to the longitudinal structuring, the top gate 50d may be structured, e.g., segmented and/or profiled, along the lateral direction (or transvers direction) D3. In the aspect shown in FIG. 11D, the top gate 50d comprises a plurality of electrodes 50d-1, 50d-2, . . . , 50d-12.

The top gate 50d enables increasing the pitch between the conveyor gates 50b whilst maintaining the ability to shuttle the one or more qubits along the at least one path 45. Furthermore, the structured, e.g., segmented, top gate 50d shown in 11D enables tuning the Rabi frequency of the EDSR generated by the magnetic field of the at least one magnet 35 and the applied AC electric field, e.g., by applying one or more adjustment voltages to one or more of the plurality of electrodes 50d-1, 50d-2, . . . , 50d-12 of the top gate 50d (see below).

In an aspect of the disclosure, the at least one surface 14 may further comprise a back surface 142. The at least one back gate 50c may be arranged on the back surface 142 of the semiconductor heterostructure 12 opposite the top surface 141 (see FIG. 3D). In the aspect shown in FIG. 3D, the back surface 142 is arranged at a bottom of the semiconductor heterostructure. The back surface 142 is arranged opposite the top surface 141. The back surface 142 may be a surface of the layer of silicon dioxide 62 (describe above).

In the aspect shown in FIG. 3D, the at least one back gate 50c extends along a shuttling direction or longitudinal direction D2 of the shuttling lane 16. The at least one back gate 50c may further extend laterally (or transversely to the at least one path 45). For example, the at least one back gate 50c may further extend along the lateral (or transverse) direction D3 of the shuttling lane 16 transverse to the at least one path 45. The at least one back gate 50c may overlap or intersect the screening gates 50a in the lateral direction D3. The at least one back gate 50c may be arranged opposite the screening gates 50a. A voltage may be applied to the at least one back gate 50c to provide an electrical potential to modify the confinement at the quantum well 69.

In one aspect of the disclosure, the at least one back gate 50c may be structured, e.g., segmented and/or profiled, along the shuttling direction (or longitudinal direction) D2. In another aspect of the disclosure, the at least one back gate 50c may be structured, e.g., segmented and/or profiled, along the lateral direction D3, i.e., transverse to the at least one path 45. In a yet a further aspect of the disclosure, the at least one back gate may be structured, e.g., segmented and/or profiled, along the shuttling direction (or longitudinal direction) D2 and the lateral direction D3.

As shown in, e.g., FIG. 3B, the screening gates 50a and the conveyor gates 50b are separated by the insulating or dielectric layer 60. As explained above, the insulating or dielectric layer 60 may be planarized during manufacturing before arranging the conveyor gates 50b on the insulating or dielectric layer 60. The four electrode subsets of the conveyor gates 50b are separated by further insulating or dielectric layers or material (not shown).

Furthermore, the dielectric or insulating layer 66 may be provided on the semiconductor heterostructure 12 (see FIGS. 3B and 4B). The insulating or dielectric layer 66 separates the screening gates 50a and the semiconductor heterostructure 12. The screening gates 50a may be provided on the insulating layer 66.

The shuttling lane 16 is configured to move (shuttle) the one or more qubits along the at least one path 45. During the operation of the quantum processor 10, the shuttling lane 16 will be used to move the one or more qubits, e.g., from the initialization zone 22 to the manipulation zone 20 and thence to the readout zone 24. During this sequence of actions on the one or more qubits, the two screening gates (or “gates”) 50a-1, 50a-2 (see FIGS. 3A and 3C) of the screening gates 50a of the shuttling lane 16 may in one aspect of the disclosure be provided with the same voltage of, e.g., 0V. The conveyor gates 50b are provided with AC voltages to provide the one or more travelling potential wells in which the one more qubits may be moved (shuttled). The AC voltages provided to the conveyor gates 50b may be sine-wave voltages. In another aspect, the AC voltages provided to the conveyor gates 50b may be non-sine-wave voltages. Alternatively, the AC voltages provided to the conveyor gates 50b may be non-periodic voltages. The AC voltages provided to the conveyor gates 50b may be phase-shifted between the electrode subsets of conveyor gates 50b-1, 50b-2, 50b-3, 50b-4. The phase shifts of the conveyor gates 50b-2, 50b-3, 50b-4 with respect to the conveyor gates 50b-1 may be set to π/2, π, and π/2, respectively. However, other settings for the phase shifts are conceivable. The phase shifts may deviate from being set to multiples of π/2.

A lateral or transverse position in the lateral direction D3 of the trajectory 80 (see FIG. 5) of the one or more qubits along the at least one path 45 (extending along the x-axis of FIG. 5) is defined by the voltage applied to the two gates 50a-1, 50a-2 (see, e.g., FIG. 3C) of the screening gates 50a. If the voltage applied to the gate 50a-1 and the voltage applied to the gate 50a-2 are substantially equal, one or more lateral positions of the generated one or more potential wells (i.e., of one or more minima of the one or more potential wells) will be substantially in the middle of the two gates 50a-1, 50a-2. If on the other hand the voltage applied to the gate 50a-1 and the voltage applied to the gate 50a-2 differ, the lateral position of the generated one or more potential wells (i.e., of the one or more minima of the one or more potential wells) will be off the middle of the two gates 50a-1, 50a-2. The differing voltages on the gates 50a-1, 50a-2 may be the result of changing either the voltage applied to the gate 50a-1 or the voltage applied to the gate 50a-2 by the addition of an adjustment voltage ΔV. In other words, the voltage applied to either the gate 50a-1 or the gate 50a is changed to V+ΔV. For example, in the case of the heterostructure 12 being an undoped Si/SiGe heterostructure, if the voltage applied to the gate 50a-1 is decreased relative to the voltage applied to the other gate 50a-2, the one or more positions of the generated one or more potential wells (i.e., of the one or more minima of the one or more potential wells) will be moved towards the other gate 50a-2. In case the heterostructure 12 is doped, such as when using GaAs/AlGaAs, increasing the voltage applied to the gate 50a-1 moves the one or more potential wells towards the other gate 50a-2. In this way, the trajectory 80 of the one or more qubits along the at least one path 45 may be shifted laterally (i.e., in the lateral or transverse direction D3 with respect to the at least one path 45).

In one aspect of the disclosure, the lateral shifting of the trajectory 80 of the of the one or more qubits may be transient (termed “local shift” in FIG. 5). The transient lateral shifting is the result of a time-varying adjustment voltage ΔV(t) being added to the voltage applied to the gate 50a-1 or the voltage applied to the gate 50a-2. In other words, the trajectory 80 deviates only temporally from the lateral position that was initially set during a calibration (i.e., y-position of 0 nm in the example shown in FIG. 5). The temporal lateral shifting results for example in the trajectory 80-1 shown in FIG. 5.

In one aspect, the time-varying adjustment voltage ΔV(t) may be an AC voltage, such as a square pulse or a square wave. If several fidelity-reducing loci 70 are on average found to be distanced along the at least one path 45 (along the x-axis in FIG. 5) from one another by an average distance of 1000 nm (or 1 μm), and the shuttling speed at which the one or more qubits are shuttled along the at least one path 45 is 10 nm/ns (or 10 m/s), then on average the one or more qubits take a time of 100 ns to travel a distance equal to the average distance. The time-varying adjustment voltage ΔV(t) may thus last for the time of 100 ns. For instance, half the period of the square wave may be chosen to be equal to the time of 100 ns. In other words the square wave may be chosen to have a frequency of 5 MHz.

In a further aspect of the disclosure, the adjustment voltage comprises a DC voltage that is added to the AC voltage applied to the conveyor gates 50b. The DC voltage may be applied to the conveyor gates 50b in addition to, or alternatively to the adjustment voltage ΔV(t) applied to the screening gates 50a. The further adjustment voltage may provide an alteration of the confinement provided by the conveyor gates 50b, e.g., enhance the confinement when the one or more qubits are in the vicinity of a fidelity-reducing locus 70 (see below).

The lateral shifting of the lateral position of the trajectory 80-1 enables circumventing a fidelity-reducing locus 70 in the shuttling lane 16. When the one or more qubits pass the fidelity-reducing locus 70 in the shuttling lane 16, the shuttling fidelity F may be reduced. The reduced shuttling fidelity F results in a less reliable shuttling of the one or more qubits along the shuttling lane 16. The fidelity-reducing locus 70 may be the result of, for example, a manufacturing impurity, a manufacturing defect, a charge defect, a crystal defect, and/or a locally reduced valley splitting. FIG. 5 shows a greyscale-coded valley-splitting landscape with valley-splitting energies between 0 μeV and 300 μeV (lighter shaded areas corresponds to higher valley-splitting energies; darker shaded areas correspond to lower valley-splitting energies). Fidelity-reducing loci 70 are located where the valley-splitting energy is between 0 μeV and approximately 30-50 μeV (shown by the paler shaded areas within dark shaded areas, some of which are surrounded by dashed ellipses). In the example shown in FIG. 5, the trajectory 80-1 circumvents several fidelity-reducing loci 70 positioned at the y-position of 0 nm. The fidelity-reducing loci 70-1, 70-2, 70-3, . . . , 70-10 are indicated by arrows and in some cases additionally by white dotted elliptical markings. In the example shown, the deviation Δy from the lateral position of the trajectory 80 initially set during a calibration (i.e., the y-position of 0 nm set during a calibration step described below) peaks at approximately 20 nm in the lateral direction D3 along the positive y-axis in FIG. 5 and at approximately −20 nm in the lateral direction D3 along the negative y-axis in FIG. 5. In another case, the maximum values for the deviation Δy in the two lateral directions (along the positive and the negative y-axis, respectively) may differ from 20 nm and −20nm, respectively.

The lateral shifting of the lateral position y of the trajectory 80-1 further enables continuous adjustment of the lateral position y of the trajectory 80-1 by means of a time-varying adjustment voltage ΔV(t). The time-varying adjustment voltage ΔV(t) results in a time-varying deviation Δy(t). The continuous adjustment may be required in the case of fluctuations in the voltages applied to the plurality of gate electrodes 50.

In an aspect of the disclosure, similar to the lateral shifting described above, one or more vertical positions of the one or more potential wells may be shifted vertically, i.e., in a stacking direction D1 (described below). Thereby, a vertical position of the trajectory 80-3 (a position along the stacking direction D1) may be altered. When the voltage applied to the at least one back gate 50c is changed, the confinement of the one or more potential wells is altered. The voltage applied to the at least one back gate 50c may be changed relative to the voltage applied to the screening gates 50a. Depending on the location of the at least one fidelity-reducing locus 70 (indicated by an asterisk in FIG. 3D), the vertical position of the trajectory 80 may be altered upwards or downwards in the stacking direction D1. Thereby, the at least one fidelity-reducing locus 70 may be circumvented, and the reliability (i.e., the fidelity) of the shuttling lane 16 may be increased.

The determination of the shuttling fidelity F enables identifying positions of the fidelity-reducing loci 70 at the trajectory 80-1 or 80-3 (e.g., along and/or in the vicinity of the trajectory 80-1 or 80-3). During the identification of the positions of the fidelity-reducing loci 70, the applied voltages V are iteratively adjusted. Thereby, the lateral position of the trajectory 80-1 and/or the vertical position of the trajectory 80-3 is iteratively adjusted. The identification of the positions of the fidelity-reducing loci 70 results in a method of controlling the shuttling lane 16.

In one aspect of the disclosure, the lateral shifting and/or the vertical shifting of the trajectory 80 may be used at the manipulation zone 20 for moving the one or more qubits to a manipulation position that does not coincide with a fidelity reducing locus 70.

The T-junction 18 shown in FIG. 6A comprises the shuttling element 16 along the at least one path 45.

The T-junction 18 further comprises a second one 16′ of the shuttling element 16 (referred to as “second shuttling element”) along the branch 45′. As shown in FIG. 6A, the second shuttling element 16′ has two screening gates 50a′-1 and 50a′-2 extending along a second longitudinal (or shuttling) direction D2′. The second shuttling element 16′ further comprises shuttling gates (or finger gates) 50b′. The shuttling gates 50b′ extend in a second transverse (or lateral) direction D3′.

The at least one path 45 and the at least one branch 45′ are arranged substantially perpendicular to one another. The second longitudinal direction D2′ is perpendicular to the longitudinal direction D2. The second lateral direction D3′ is perpendicular to the lateral direction D3.

The shuttling element 16 (referred to as “first shuttling element”) and the second shuttling element 16′ join one another at a junction 28. The at least one path 45 and the branch 45′ meet one another at the junction 28. The two screening gates 50a′-1 and 50a′-2 end at the junction 28. The conveyor gates 50b′ end at the junction 28.

The screening gate 50a-1 of the first shuttling element 16 is interrupted along the longitudinal direction D2 at the junction 28. The screening gate 50a-1 is interrupted where the screening gates 50a′-1 and 50a′-2 of the second shuttling element 16′ end. The screening gate 50a-1 is interrupted where the first shuttling element 16 and the second shuttling element 16′ join one another at a junction 28. The interruption may extend along the lateral direction D3′ between at least the screening gates 50a′-1 and 50a′-2.

The screening gates 50a′-1 of the second shuttling element 16′ may be connected to one portion of screening gate 50a-1 of the first shuttling element 16. The screening gates 50a′-2 of the second shuttling element 16′ may be connected to another portion of screening gate 50a-1 of the first shuttling element 16. The screening gates 50a-1 and 50a′-1 (50a-1 and 50a′-2) may be joined electrically in such a way that the screening gates 50a-1 and 50a′-1 (50a-2 and 50a′-2) effectively form a single continuous screening gate. In another aspect, the screening gates 50a-1 and 50a′-1 (50a-1 and 50a′-2) may be designed as a single continuous screening gate. In another aspect, the screening gates 50a-1 and 50a′-1 (50a-1 and 50a′-2) may be separated by a dielectric or insulating layer.

The conveyor gates 50b′ of the second shuttling element 16′ may be arranged at the junction 28 in the second longitudinal direction D2′ (or the lateral direction D3 of the first conveyor gate 16) such that at least one of the conveyor gates 50b′ touches or overlaps the screening gate 50a-1 of the first shuttling element 16 along the second longitudinal direction D2′ (or first lateral direction D3). Ones of the conveyor gates 50b′ may have curved or angled ends in the lateral direction D3′. The ones of the conveyor gates 50b′ may be arranged in proximity to the junction 28.

In the aspect shown in FIG. 6A, the conveyor gate of the electrode subset 50b′-1 of the second shuttling element 16′ closest to the junction 28 (the “last conveyor gate 50b′”) overlaps with the screening gate 50a-1. The last conveyor gate 50b′ extends in the lateral direction D3′ at least between the screening gates 50b′-1 and 50b′-2. The last conveyor gate 50b is arranged in proximity to a lower edge (as seen in FIG. 6A) of the screening gate 50a-1 along the lateral direction D3. By applying the last conveyor gate 50b′ with the voltage such that sufficient confinement is provided to the one or more qubits, this arrangement of the last conveyor gate 50b′ enables providing a screening potential. The voltage applied to provide the confinement may be stationary. The providing of the screening potential enables compensating for the interruption of the screening gate 50a-1 in the case of shuttling of the one or more qubits along the shuttling element 16 at the junction 28.

The conveyor gates 50b of the first shuttling element 16 are arranged at the junction 28 such that the conveyor gates 50b do not contact the conveyor gates 50b′ of the second shuttling element 16′. As shown in FIG. 6A, the conveyor gates 50b of the first shuttling element 50b at the junction are arranged below (as seen in FIG. 6A) the last conveyor gate 50b′ of the second conveyor element 16′ along the lateral direction D3 (or second longitudinal direction D2′).

When the one or more qubits are moved along the branch 45′ towards the junction 28, the voltages V may be applied to the conveyor gates 50b of first shuttling element 16 to provide a quasi-stationary potential well, into the minimum of which the one or more qubits may be moved in an adiabatic manner by means of the travelling potential well moving along the second shuttling element 16′. The quasi-stationary potential well is generated by applying stationary ones of the voltages to the conveyor gates 50b of the first shuttling element 16. Once the one or more qubits have been moved to the minimum of quasi-stationary potential well provided by the conveyor gates 50b of the first shuttling element 16, the voltages applied to the conveyor gates 50b may be changed to AC voltages to move (shuttle) the one or more qubits along the at least one path 45 by means of the first shuttling element 16.

For reversing the afore-described movement, adjustments to the voltages applied conveyor gates 50b and 50b′ may be made. Thereby, differences in the confinement strengths between the first shuttling element 16 and the branch 16′ may be managed.

When the one or more qubits are located at the junction 28, the one or more qubits may be moved along the longitudinal direction D3 or along the second longitudinal direction D3′. The one or more qubits may be shuttled along the at least one path 45 without turning off into the branch 45′. The one or more qubits may be shuttled along the at least one path 45 and made to turn off along the branch 45′ (or vice versa). The T-junctions 18 thus enables moving the one or more qubits across the quantum chip 10.

FIG. 7 shows a simulation of the orbital splitting between a ground state and a first excited state of the one or more qubits during moving of the one or more qubits in a straight manner along the first shuttling element 16 (left panel). The simulation shows an orbital splitting above 1 meV for the entire simulated movement. For a shuttling speed of the order of 10 m/s, decoherence is preventable if the orbital splitting remains above roughly 1 meV, which is the case for the straight shuttling shown in the left panel of FIG. 7.

During the moving of the one or more qubits, in which the one or more qubits turn off from the second shuttling element 16′ into the first shuttling element 16 (see right panel of FIG. 7), the orbital splitting drops to below 1 meV. The orbital splitting may be improved by dynamically adjusting an offset between the conveyor gate 50b and 50b′ to increase confinement at junction 28. Another option is to adjust the shuttling speed.

FIG. 8 shows the simulation of the quasi-stationary potential well located at the junction 28 and the travelling potential well moving along the second shuttling element 16′ (as described above). The results show that the one or more qubits trapped in the travelling potential well moving along the second shuttling element 16′ can be transferred adiabatically to the quasi-stationary potential well. Tunneling of the one or more qubits can be prevented.

The method according to the present disclosure of adjusting voltages applied to the plurality of gate electrodes 50 achieves a method of controlling the quantum processor 10.

Furthermore, when the plurality of the voltages V are calibrated, at least one interaction between ones of the plurality of voltages among each other is accounted for. The at least one interaction may be expressed as a boundary condition or as a functional relationship. The functional relationship may take into account the target ranges. For example, in the case of the shuttling lane 16 shown in FIGS. 3A and 3B, the voltages applied to the screening gates 50a and to the conveyor gates 50b generate electric fields (in the case of voltages V being DC voltages) and/or electromagnetic fields (in the case of voltages V being AC voltages). The generated fields superpose each other, e.g., at trajectory 80, and lead to a resultant electric field and/or a resultant electromagnetic field. The effect of this superposition, i.e., the interaction, needs to be considered with regard to the material composition as well as the targeted behaviors of the shuttling lane 16. Other interactions among the voltages applied to the gate electrodes 50 will be present and possibly depend on the actual design of the quantum processor 10.

Based on determining a density of the fidelity-reducing loci 70 in a portion of the quantum processor 10, such as along one of the shuttling lanes 16, at the T-junction 18, or in the entire quantum processor 10, the elevated density may point to a property of a manufacturing process of the quantum processor 10 or of the materials used in the manufacturing process. In this case, the quantum processor 10 may be manufactured such that the screening gates 50a-1 and 50a-2 (see FIGS. 3A and 3B) arranged thereon are segmented.

In one aspect, the screening gate 50a-1 and/or the screening gate 50a-2 of the shuttling lane 16 may be segmented into electrically disconnected screening gate segments 50a-11, 50a-12 and/or 50a-21, 50a-22, respectively, as shown in FIGS. 4A and 4B.

In the aspect shown in FIGS. 4A and 4B, the dielectric or insulating layer 60 comprises a first dielectric or insulating layer 60a and a second dielectric or insulating layer 60b. The screening gates 50a-1 and 50a-2 and the conveyor gates 50b are separated by the first insulating or dielectric layer 60a and/or by the second insulating or dielectric layer 60b.

The dielectric or insulating layer 66 separates the screening gates 50a-1 and 50a-2 and the semiconductor heterostructure 12. In the aspect shown in FIGS. 4A and 4B, the screening gate segments 50a-11, 50a21 may be provided on the insulating layer 66. In the aspect shown in FIGS. 4A and 4B, a portion of the first dielectric and insulating layer 60a is arranged between the screening gate segments 50a-12, 50a-22 and the dielectric or insulating layer 66.

For instance, if on average two fidelity-reducing loci 70 are found per 1 μm along the at least one path 45 of the shuttling lane 16, the screening gate segments 50a-11, 50a-12, 50a-21, 50a-22 of the screening gates 50a may be designed to have lengths of no longer than approximately 500 nm. In one aspect, the screening gates 50a may be subdivided into four screening gate segments having lengths of approximately 250 nm.

The electrically disconnected screening gate segments 50a-11, 50a-12, 50a-21, 50a-22 are disconnected at a segmentation point (or disconnection point) 55. The screening gate segments 50a-11, 50a-12, 50a-21, 50a-22 of the screening gates 50a may be disconnected at the segmentation point 55 by the first dielectric or insulating layer 60a. At the segmentation point 55, the first dielectric or insulating layer 60a may be provided between the screening gate segments 50a-11 and 50a-12 and/or between the segments 50a-21 and 50a-22, respectively.

The screening gate 50a may be separated from the conveyor gates 50b by the dielectric or insulating layer 60. In one aspect, the first dielectric or insulating layer 60a may at least partially separate the screening gate 50a from the conveyor gates 50b. In this aspect, the second dielectric or insulating layer 60b may at least partially separate the screening gate 50a from the conveyor gates 50b. For example, in the aspect shown in FIG. 4B, the screening gate segments 50a-12, 50a-22 of the screening gate 50a are separated from the conveyor gates 50b by the second dielectric or insulating layer 60b. In this aspect, the first dielectric or insulating layers 60a and the second dielectric or insulating layer 60b may be partially arranged on one another. A first portion 60al of first the dielectric or insulating layer 60a may be arranged on the screening gate segments 50a-11, 50a-21 of the screening gate 50a. Furthermore, the screening gate segment 50a-12, 50a-22 of the screening gate 50a may be at least partially arranged on a second portion 60a2 of the first dielectric or insulating layer 60a. The screening gate segments 50a-12, 50a-22 of the screening gates 50a may thus be arranged at a higher level along a stacking direction D1 with respect to the segment 50a-11, 50a-21 of the screening gates 50a (see FIG. 4B).

The first dielectric or insulating layer 60a may form a step 60as at the segmentation point 55. The step 60as may be part of the first dielectric or insulating layer 60a. The first portion 60a1 and second portion 60a2 may be connected by the step 60as. The step 60as may extend in the stacking direction D1. Additionally, the step 60as may extend in the longitudinal direction D2.

In a further aspect, the shuttling lane 16 may comprise a protrusion 161. The protrusion may be located at the segmentation point 55. At the protrusion 161, protruding ones conveyor gates 50bp of the conveyor gates 50b, a protruding section 60bp of the second dielectric or insulating layer 60b, a protruding section 50a-12p of the segment 50a-12 of the screening gates 50a, and/or a protruding section 50a-22p of the segment 50a-22 of the screening gates 50a may protrude along the stacking direction D1 relative to the at least one surface 14 (see FIG. 4B). The protruding ones of the conveyor gates 50bp of the conveyor gates 50b, the protruding section 60bp of the second dielectric or insulating layer 60b, the protruding section 50a-12p of the screening gate segment 50a-12 of the screening gates 50a, and/or the protruding section 50a-22p of the screening gate segment 50a-22 of the screening gates 50a may protrude relative to the conveyor gates 50b, the second dielectric or insulating layer 60b, the screening gate segment 50a-12 and/or the screening gate segment 50a-22, respectively. The conveyor gates 50bp, the section 60bp, the section 50a-12p, and the section 50a-22p may thus be arranged at a higher level along the stacking direction D1 with respect to the conveyor gates 50b, the second dielectric or insulating layer 60b, the screening gate segment 50a-12, and the screening gate segment 50a-22, respectively. The protruding section 60bp of the second dielectric or insulating layer 60b may have portions that extend in the stacking direction D1. The protruding section 60bp of the second dielectric or insulating layer may envelop the protruding section 50-12p of the screening gate segment 50a-12 and/or the protruding section 50-22p of the screening gate segment 50a-22. The protrusion 161 may extend in the lateral (transverse) direction D3 across the screening gate 50a-1 and/or the screening gate 50a-2.

In another aspect, the protruding section 50a-12p of the screening gate segment 50a-12 and/or the protruding section 50a-22p of the screening gate segment 50a-22 of the screening gate 50a may be arranged to touch or intersect along the longitudinal direction D2 a line L extending along the stacking direction D1 (see FIG. 4B). The line L may also be touched along the longitudinal direction D2 by the screening gate segment 50a-11 and/or the screening gate segment 50a-21 of the screening gates 50a. In a further aspect, the screening gate segment 50a-12 and/or the screening gate segment 50a-22 may intersect the line L or overlap with the line L. In yet a further aspect, the screening gate segment 50a-11 and/or the screening gate segment 50a-21 may intersect the line L or overlap with the line L along the longitudinal direction D2. In other words, by means of the protruding section 50a-12p and/or 50a-22p, the screening gate segment 50a-11 and/or 50a-21 may overlap with the screening gate segment 50a-12 and/or 50a-22, respectively, in the shuttling direction (or longitudinal direction) D2 (see FIG. 4B)without contacting one another. Arranging the screening gate segment 50a-11 and/or the screening gate segment 50a-21 to overlap in the shuttling direction (or longitudinal direction) D2 in contactless manner with the screening gate segment 50a-12 and/or 50a-22, respectively, enables providing a continuous potential by means of the voltage applied to the screening gate segment 50a-11, 50a-12 of the screening gate 50a-1 and/or the voltage applied to the screening gate segment 50a-21, 50a-22 of the screening gate 50a-2.

Alternatively, the shuttling lane 16 does not have the protrusion 161. In this case, the second dielectric or insulating layer 60b may have a planar surface. Furthermore, the conveyor gates 50b will in this case be arranged a the same level in the stacking direction D1; or the electrode subsets 50b-1, 50b-2, 50b-3, 50b-4 will individually be arranged at the different levels (see above) in the stacking direction D1, without any conveyor gates 50b protruding.

In yet another aspect, a gap in the screening gate 50a-1 and/or 50a-2 may be provided along the shuttling direction (or longitudinal direction) D2 at the segmentation point 55, where the screening gate 50a-1 and/or 50a-2 are separated into segments. The gap may be provided in the shuttling direction (or longitudinal direction) D2 between the screening gate segments 50a-11, 50a-12 of the screening gate 50a-1 and/or between the screening gate segments 50a-21, 50a-22 of the screening gate 50a-2. The step 60as may be provided in the gap. In this aspect, none of the conveyor gates 50b may be arranged above the gap in the stacking direction D1. Arranging the conveyor gates 50b, which provide the potential wells for moving (shuttling) the one or more qubits, without any overlap of the conveyor gates 50b with the gap avoids the conveyor gates 50b generating a potential that interferes with the potential defining the trajectory 80 provided by the screening gates (or path-defining gates) 50a-1, 50a-2.

Segmenting the screening gates 50a into the screening gate segments 50a-11, 50a-12 and/or 50a-21, 50a-22 enables applying the voltages individually to the screening gate segments 50a-11, 50a-12 and/or 50a-21, 50a-22. The voltages that are individually applied to the screening gate segments 50a-11, 50a-12 and/or 50a-21, 50a-22 may be DC voltages, in which case, given a corresponding duration of the DC voltages, the trajectory 80-2 will be constant along the screening gate segments 50a-11, 50a-12 and/or 50a-21, 50a-22, as seen in the FIG. 5. In the example shown in FIG. 5, the screening gate 50a is segmented into three segments, to which individual DC voltages are applied, as can bee seen from the position of the trajectory 80-2 relative to the line with y=0 nm.

The one or more segmentation points (or disconnection points) 55 may be arranged in the quantum processor 10 based on the determined density of fidelity-reducing loci 70. Based on a distribution of the fidelity-reducing loci 70 that is derived from the positions of the identified fidelity-reducing loci 70, the segmentation points 55 may be arranged in the quantum processor 10. Assuming, for example, a Gaussian distribution of distances between the fidelity-reducing loci 70, with an average distance d and with a standard deviation of σ_{d}, the segmentation points 55 may be arranged in the quantum processor 10 with a distance of, for example, approximately d−2×σ_{d} between any two of the segmentation points 55.

In one aspect of the disclosure, the screening gate 50a-1 and the screening gate 50a-2 are segmented into the screening gate segments 50a-11, 50a-12 and 50a-21, 50a-22, respectively. Alternatively, one of the screening gate 50a-1 and the screening gate 50a-2 is segmented. In this case, the screening gate 50a-1 is segmented into the screening gate segments 50a-11, 50a-12, or the screening gate 50a-2 is segmented into the screening gate segments 50a-21, 50a-22.

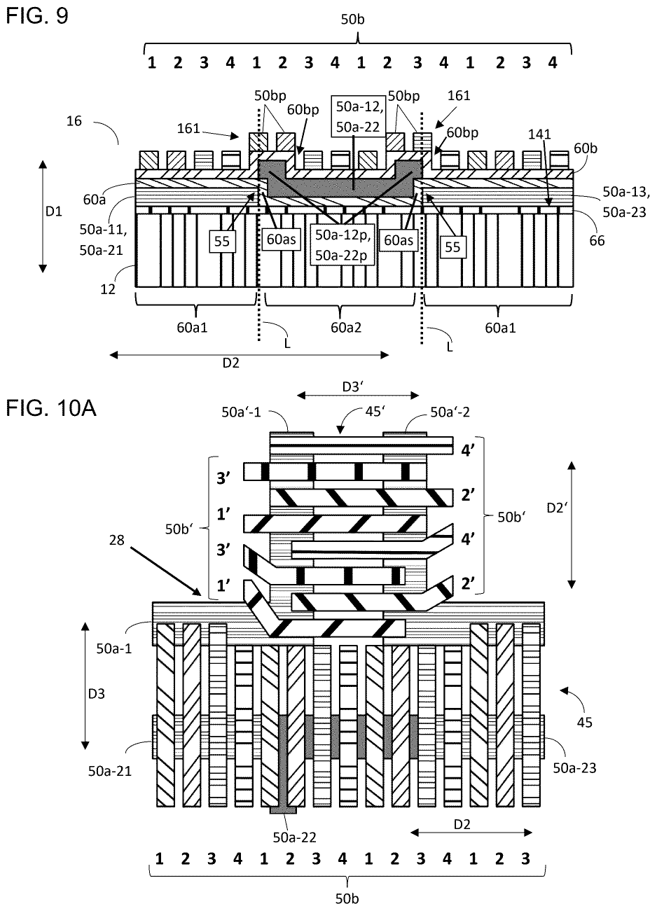

FIG. 9 shows an aspect of the disclosure, in which the shuttling lane 16 has two of the segmentation point 55. The screening gate 50a-1 is segmented into three segments 50a-11, 50a-12, 50a-13, and/or the screening gate 50a-2 is segmented into three segments 50a-21, 50a-22, 50a-23.

The shuttling lane 16 may contain two of the protrusion 161, as described above. Likewise, the conveyor gates 50b may comprise two of the protruding ones conveyor gates 50bp, as described above. Likewise, the second dielectric or insulating layer 60b may comprise two of the protruding section 60bp, as described above. The two of the protruding section 60bp may belong to a single one of the dielectric or insulating layer 60b, as shown in FIG. 9. Likewise, the screening gate 50a-1 may comprise two of the protruding section 50a-12p, as described above; and/or the screening gate 50a-12 may comprise two of the protruding section 50a-22p, as described above. The two of the protruding section 50a-12p may belong to a single one of the screening gate section 50a-12, as shown in FIG. 9. The two of the protruding section 50a-22p may belong to a single one of the screening gate section 50a-22, as shown in FIG. 9. The first dielectric or insulating layer 60a may comprise two of the step 60as. The two of the step 60as may belong to a single one of first dielectric or insulating layer 60a, as shown in FIG. 9.

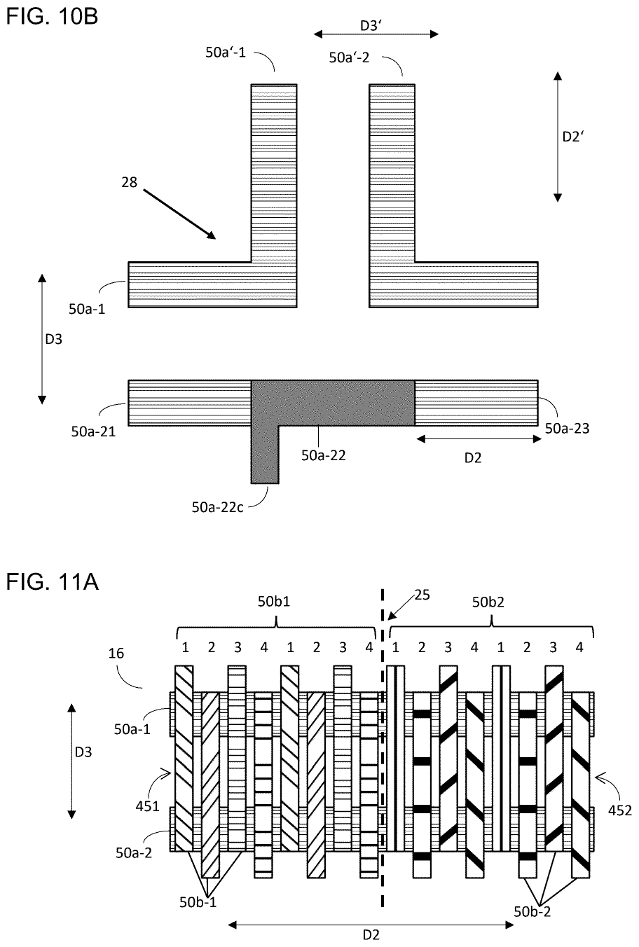

FIGS. 10A and 10B show an application of the aspect of the disclosure shown in FIG. 9 to the T-junction 18 shown in FIG. 6A. The screening gate 50a-2 of the first shuttling element 16 of the screening gate 18 is segmented into three segments as described with reference to FIG. 9 The segment 50a-22, as shown in FIGS. 10A and 10B, may be arranged at the junction 28. This arrangement enables adjusting the voltage applied to the screening segment 50a-22 in the case of the presence of the fidelity-reducing locus 70 at the junction 70. The adjustment voltage ΔV may be added to the voltage applied to the screening gate segment 50a-22 in order to circumvent the fidelity-reducing locus 70 located at the junction 28 by changing the trajectory 80, or to counteract the effect of the fidelity-reducing locus 70 located at the junction 28 by increasing the confinement generated by the screening gate segment 50a-22, possibly in conjunction with the last conveyor gate 50b′ of the second shuttling element 16′. The screening gate segment 50a-22 has a contact 50a-22c for applying the adjustment voltage ΔV.

The manipulation zone 20 is configured to manipulate the one or more qubits at the least one magnet 35. During the operation of the quantum processor 10, the manipulation zone 20 will be used to manipulate the one or more qubits. The manipulating may be a single-qubit action or two-qubit action.

FIG. 3E shows a line cut of a temporal sequence (in four panels I, II, III, IV) of a simulation of an evolution of a potential energy landscape generated by applying voltages to the gate electrodes 50 to move two qubits (represented by the filled circles) towards the interface 25 (indicated by the dashed vertical line) and of lowering the tunnel barrier between the two qubits to achieve an exchange interaction J. The detuning between the confinement potentials for the two qubits is zero in this simulation. The x-axis represents the distance from the interface 25 along the shuttling direction D2. The y-axis represents the potential energy (or confinement energy). The horizontal bars above the potential energy represent relative values of the voltages applied to the conveyor gates 50b at the interface 25.

Using two shuttling elements 16 that meet an the interface 25 enables the independent control of both the distance between the two qubits at the interface and the tunnel barrier between the two qubits. Effectively, an independent control of tunnel barrier height and width results in lower charge noise sensitivity and an increased robustness against disorder. Compared to multi-quantum dot arrays, control is significantly simplified since high outer barriers are achieved automatically during shuttling and only the interdot barrier needs to be controlled precisely. The actual gate operation is based on adiabatically turning on the exchange interaction J which shifts the energy levels of the antiparallel spin states in such a way that they acquire additional phases. After accumulating phases for t=πh/J(t), subsequent single-qubit gates allow the implementation of a CPHASE gate.

In one aspect of the disclosure, the single-qubit action is the rotating of the one or more qubits by means of the EDSR, which is based on moving, by applying the AC electric field, one or more wave functions of the one or more electrons (or holes) trapped (confined) in the potential well that is located in the first portion 69-1 of the quantum well 69, where the first magnetic field strength of the inhomogeneous first magnetic field of the first magnet 35-1 is non-zero. The AC electric field may be generated by a microwave signal, e.g. applied to one or more of the conveyor gates 50b. The resulting Rabi frequency is given by Ω=(gμ_{B}E₀/2κ)(dB_{⊥}/dx), where g is the g-factor, μ_{B} the Bohr magneton, E₀ an amplitude of the AC electric field, dB_{⊥}/dx a gradient in the shuttling direction D2 (represented by x) of the magnetic field of the at least one magnet 35 transverse to the external magnetic field B₀ (the transverse component of the magnetic field of the at least one magnet 35 described above), and κ the curvature of the confining potential well, which in the first approximation may be described by a parabolic potential (½) κx² around a minimum of the confining potential well at x=0. The strength of the confining potential and the orbital level splitting are determined by the curvature κ. From the equation for the Rabi frequency Ω it can be seen that a change Δκ in the curvature κ of the confining potential well results in a change ΔΩ in the Rabi frequency Ω given by ΔΩ=−(Ω/κ) Δκ.

In one aspect of the disclosure, the one or more qubits are moved (shuttled) in an oscillatory manner at a location of a maximum of the gradient in the shuttling direction D2 of the magnetic field of the at least one magnet 35 transverse to the external magnetic field B₀. For high fidelity single-qubit gates, an amplitude of the oscillatory moving of the one or more qubits is estimated to be on the order of 20 nm, which is significantly larger than for conventional EDSR, where the amplitudes are on the order of a few picometers. The higher amplitude allows for using weaker magnetic field gradients, which in turn increases the overall robustness against charge noise.

The change Δκ in the curvature κ of the confining potential may be generated by applying one or more adjustment voltages to one or more of the plurality of electrodes 50d-1, 50d-2, . . . , 50d-12 of the top gate 50d.

We consider an adjustment voltage ΔV applied to a single electrode (termed hereafter “tuning gate”) of the plurality of electrodes 50d-1, 50d-2, . . . , 50d-12 of the top gate 50d. This tuning gate may be located at the first portion 69-1 or at the second portion 69-2 of the quantum well 69. The tuning gate may be located in the vicinity of the potential well in which the one or more qubits are trapped. For instance, in the case of FIG. 11D, the tuning gate may be one of the electrodes 50d-2, 50d-3, 50d-6, 50d-7, or 50-d8 of the top gate 50d, but is not limited thereto. If the potential well in which the one or more qubits are trapped is located in the first portion 69-1 or the second portion 69-2, the Rabi frequency for rotating the one or more qubits may be changed. The adjustment voltage ΔV applied to the tuning gate results in an adjustment potential that may be modelled as a potential generated by a dipole line oriented perpendicular to the shuttling direction D2 (i.e., oriented in the lateral or transverse direction D3) and pointing in the stacking direction D1: φ_{adj}=φ_{adj,0}(d²/(d²+x²)), where φ_{adj,0} is a prefactor proportional to the adjustment voltage ΔV applied to the tuning gate relative to the voltages applied to plurality of gate electrodes 50 and the width of the tuning gate, x is the position along the shuttling direction D2, and d is a distance between the dipole line and the at least one path 45. Furthermore, the potential well in which the one or more qubits are trapped may be modelled as φₛ=φₛ₀cos(k(x−x₀(t) where k=2π/λ, λ is the spatial period, φₛ₀ is a prefactor determined by the voltages applied to the conveyor gates 50b, and x₀ is a position along the shuttling direction D2 of the minimum of the potential well in which the one or more qubits are trapped.

In order to maintain the one or more qubits trapped in the potential well, there is an upper bound for the adjustment voltage ΔV applied to the tuning gate. The upper bound for the adjustment voltage ΔV may correspond to an upper bound for the prefactor given by |φ_{adj,0}|<(4.8 d/λ)|φₛ₀|. The adjustability or tunability of the Rabi frequency Ω is quantified by the ratio of the confining strengths (or curvatures) of the adjustment potential and the shuttling potential, i.e., by the ratio of the second derivative d²φ_{adj}/dx² and d²φₛ/dx². The upper bound for the adjustment voltage estimated above leads to an adjustability (or adjustment range) or tunability (or tuning range) of the Rabi frequency Ω of 0.25 d/λ. For typical values of d=50 mm and λ=300 nm, the tuning range of the confinement strength is thus by a factor 1.5 larger than the confinement due to the shuttling potential φₛ alone. For a deconfining adjustment (or deconfining tuning) of the Rabi frequency Ω, it is advisable to remain below the upper bound in order to retain a shape of the potential well that has a harmonic minimum. Further considerations lead to the conclusion that an amplitude of the displacement of the one or more qubits in the inhomogeneous magnetic field are bound by approximately 15 nm in order to ensure that the potential well may be approximated by the first order quadratic potential that is described by the curvature κ.

Examples of the adjustment potential φ_{adj} as well as the resulting sum of the adjustment potential φ_{adj} and the shuttling potential φₛ (which may also be referred to as “adjusted potential well”) are shown in the upper panel of FIG. 12, where values of d=50 nm and λ=300 nm were chosen. Two examples of the adjusted potential well are shown with the adjustment voltage weakening the confinement (“deconfining”) or strengthening the confinement (“confining”). The corresponding non-adjusted potential well is shown with the adjustment voltage not changing the confinement (“unperturbed”). The solid lines indicate the adjusted potential well. The dashed lines indicate the adjustment or tuning potential φ_{adj}. A Gaussian charge density indicating the spatial distribution of the one or more qubits that are trapped in the potential well is shown. As explained above, the adjusted potential well results in the adjusted Rabi frequency Ω.

In another aspect of the disclosure, in the case of the presence of a non-zero gradient dB₈₁ /dx in the shuttling direction D2 of a magnetic field of the at least one magnet 35 parallel to the external magnetic field B₀ (the parallel component of the magnetic field of the at least one magnet 35 described above), the splitting of the spin-dependent energy levels by means of the external magnetic field B₀ may be adjusted by changing an average position of the minimum of the potential well by means of another one of the adjustment potential. This adjustment potential may be generated by applying the adjustment voltage ΔV to one or more of the electrodes 50d-1, 50d-2, . . . , 50d-12 of the top gate 50d. The applying of the adjustment voltage may result in the changing of an average position of the one or more qubits trapped in the potential well.

We consider adjustment voltages ΔV applied to two electrodes (“tuning gates”) of the one or more of the electrodes 50d-1, 50d-2, . . . , 50d-12 of the top gate 50d. The two tuning gates may be located in the vicinity of the potential well in which the one or more qubits are trapped. For instance, in the case of FIG. 11D, the two tuning gates may be chosen from the electrodes 50d-2, 50d-3, 50d-6, 50d-7, or 50-d8 of the top gate 50d, but are not limited thereto. In one aspect, the two tuning gates may be located around the position of the potential well. For example, the two tuning gates may be located at a distance of the minimum of the potential well along the shuttling direction D2. The two tuning gates may comprise a first tuning gate located in FIG. 11D on the left of the minimum of the potential well, and a second tuning gate located in FIG. 11D on the right of the minimum of the potential well. If the potential well in which the one or more qubits are trapped is located in the first portion 69-1 or the second portion 69-2, the afore-mentioned choice of the two tuning gates will result in a changed average position of the potential well, e.g., the minimum of the potential well, in which the one or more qubits are trapped. The changed average position of the potential well results in a changed magnetic field generating the spin-dependent energy levels B₀+ΔB₀with ΔB₀=(dB₈₁ /dx) Δx. As a result of the changed magnetic field the resonance frequency v=(gμ_{B}/h)B₀ changes by Δv=(gμ_{B}/h)ΔB₀.

One example of the adjustment potential φ_{adj} as well as the adjusted potential well are shown in the lower panel of FIG. 12, where values of d=50 nm and λ=300 nm were chosen. An example of the adjusted potential well is shown with the adjustment voltage changing the position of the minimum of the potential well (“shifting”). The corresponding non-adjusted potential well is shown with the adjustment voltage not changing the position of the minimum of the potential well (“unperturbed”). The solid lines indicate the adjusted or non-adjusted potential well. The dashed lines indicate the adjustment or tuning potential φ_{adj}, which is here the sum of potentials generated by dipole lines with opposing values of the adjustment voltages applied thereto. Furthermore, a Gaussian charge density indicating the spatial distribution of the one or more qubits that are trapped in the potential well is shown. As explained above, the adjusted potential well results in the adjusted resonance frequency.

The considerations regarding upper bounds of the adjustment voltages similarly apply in the case of adjusting the resonance frequency in order not to compromise shuttling of the one or more qubits. Similar assumptions (see above) lead to maximal shifts of the sum of minimum of the potential well and the displacement of the one or more qubits trapped within the potential well by about 15 nm.

In a further aspect of the disclosure, the potential barrier (or tunnel barrier) and the detuning at the interface 25 may be adjusted. The adjustment voltages ΔV may be applied to one or more of the electrodes 50d-1, 50d-2, . . . , 50d-12 of the top gate 50d. For instance, one of the adjustment voltages ΔV may be applied to the electrode 50d-8 to increase or decrease the tunnel coupling across the potential barrier (tunnel barrier). Others of the adjustment voltages ΔV may be applied to the electrodes 50d-7 and 50d-9 to change the detuning between the at least one first stationary potential well and the at least one second stationary potential well.

In another aspect of the disclosure, the adjusting voltages may be applied to the conveyor gates 50b instead of to one or more of the electrodes 50d-1, 50d-2, . . . , 50d-12 of the top gate 50d. In the aspects of the disclosure shown in FIGS. 11B and 11C, the conveyor gates 50b have electrode subsets 50b1-1, 50b1-2, 50b1-3, 50b1-4, 50b2-1, 50b2-2, 50b2-3, 50b2-4 that are independently supplied with voltages. In the aspect shown in FIG. 11D, at least three electrodes belonging to the electrode subsets 50b1-2, 50b1-3, 50b1-4 are located at the first portion 69-1 of the quantum well 69. Furthermore, at least three electrodes belonging to the electrode subsets 50b1-3, 50b1-4, 50b2-1 are located at the second portion 69-2 of the quantum well 69. One or more of the electrode subsets may be supplied with an AC voltage for shuttling the potential wells and with adjustment voltages (DC voltages) for adjusting the manipulation parameters in a similar manner as when the adjustment voltages are applied to the electrodes 50d-1, 50d-2, . . . , 50d-12 of the top gate 50d.

The foregoing examples of adjusting the Rabi frequency Ω, the resonance frequency v, or the exchange coupling J explain how the manipulation fidelity F_{M} may be increased by adjusting parameters relating to the manipulating of the one or more qubits (or “manipulation parameters”). The manipulation parameters comprise the Rabi frequency Ω, the resonance frequency v, and the exchange coupling J. The adjusting of the manipulation parameters enables overcoming the effect of fidelity-reducing loci or disorder in the quantum well 69. The fidelity-reducing locus 70 may be the result of, for example, a manufacturing impurity, a manufacturing defect, a charge defect, a crystal defect, and/or a locally reduced valley splitting. The fidelity reducing locus 70 may further be the result of the non-zero magnetic field strength, parallel to the external magnetic field B₀, of the at least one magnet 35, which may affect the Rabi frequency Ω (as can be seen from, e.g., formula (2) in Kloeffel and Loss, Prospects for Spin-Based Quantum Computing, 2012). When it is determined that the manipulation fidelity F_{M} does not meet the requirements for a reliable operation of the quantum processor 10, adjusting one or more of the manipulation parameters enables increasing the manipulation fidelity F_{M}.

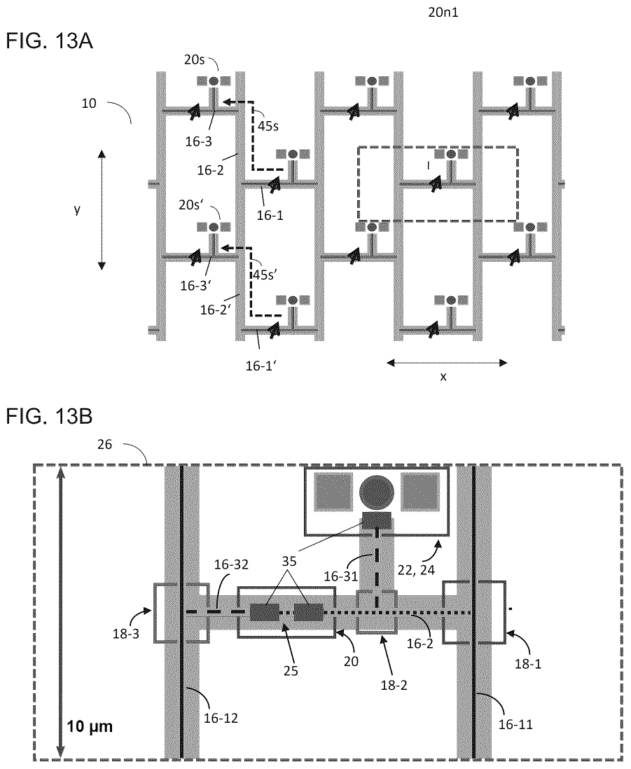

FIG. 13A shows another aspect of quantum processor 10 according to the disclosure. The quantum processor 10 shown in FIG. 13 A has several unit cells 26, one of which is shown in FIG. 13B. The quantum processor 10 has a plurality of manipulation zones 20, a plurality of components 22, 24 for initialization and readout, a plurality of T-junctions 18, and a plurality of shuttling lanes 16.

In the aspect shown, the several unit cells 26 have the same layout. However, in another aspect, the several unit cells 26 may not all have the same layout. For example, a number of T-junctions 18 of a selected unit cell 26 (indicated by the dashed rectangle) may be three (as shown in FIG. 13A) or may be a different number.

As shown in FIG. 13B, any one of the unit cells 26 of the quantum processor 10, shown in FIG. 13A, has one of the manipulation zone 20, one of the component 22, 24 for initialization and readout, and two ones of the T-junction 18. However, in one aspect, one or more of the unit cells 26 may have no component 22, 24 for initialization and readout. In another aspect, the manipulation zones 20 of two adjacent unit cells 26 may be directly connected by a shuttling lane 16 (i.e., without having a T-junction 18 arranged therebetween).

FIG. 13B shows an aspect of a unit cell 26 of the quantum processor 10 shown in FIG. 13B. The unit cell 26 shown in FIG. 13B comprises one of the manipulation zone 20, three ones 18-1, 18-2, 18-3 of the T-junction 18, one of the component 22, 24 for initialization and readout, and several ones 16-11, 16-12, 16-2, 16-31, 16-32 of the shuttling lane 16.

The unit cell has an extension of the order of 10 μm, as indicated by the arrow. However, the disclosure is not limited to this extension. The shuttling lane 16 according to the disclosure enables shuttling and connecting the one or more qubits of the quantum chip 10 over practically arbitrary distances. The extension shown could be 20 μm, 50 μm, or 100 μm, any value in between or beyond those given values. The extension may depend on the requirements, such as the number of the DC lines, of the AC lines, and/or of the bias tees that have to be connected to the quantum chip 10. The extension may further depend on a cooling power of a refrigerator, in which the quantum chip 10 is arranged.

The shuttling lanes 16-12 and 16-11 connect the unit cell 26 to the further unit cells 26, e.g., as shown in FIG. 13A. At the T-junction 18-1, the shuttling lanes 16-11 and 16-2 join one another, as described above. The shuttling lane 16-31 connects the component 22, 24 for initialization and readout with the T-junction 18-2. At the T-junction 18-2, the shuttling lanes 16-2 and 16-31 join one another, as described above. The shuttling lane 16-2 connects the T-junction 18-1 with the interface 25 of the manipulation zone 20. At the interface 25, the shuttling lanes 16-2 and 16-32 meet one another, as described above. The shuttling lane 16-32 connects the interface 25 with the T-junction 18-3. At the T-junction 18-3, the shuttling lanes 16-32 and 16-12 join one another, as described above.

The quantum chip 10 shown in FIG. 13A may be used for implementing codes for quantum error correction. One example of a code for quantum error correction is a surface code. One example of a surface code for quantum error correction has been proposed by Fowler et al. (2012 [symbol] Phys. Rev. A 86, 032324).

Surface codes allow the detection of errors rather than their correction. Measuring more than one qubit at a time allows non-destructive quantum error detection. Corrections can then be subsequently implemented in classical electronics. Corrections are performed by suitable actions, e.g., single-qubit operation, on the faulty qubits.

The surface code is operated as a so-called stabilizer code. Products of suitable operations are called stabilizers. Stabilizers are helpful in preserving quantum states: By repeatedly measuring a quantum system using a complete set of commuting stabilizers, the system is brought into a simultaneous and unique eigenstate of all the stabilizers. Measuring the stabilizers enables not perturbing the system. A change in a measurement result indicated one or more qubit errors. The quantum state is projected onto a different stabilizer eigenstate by the measurements Evaluating the stabilizer eigenstate allows the detection of qubit errors.

Physical qubits are either data qubits in which the computational quantum states are stored, or measurement qubits. Measurement qubits are also called ancilla qubits. By choosing a suitable amount of data and ancilla qubits, at least thirteen physical qubits are used to implement a single logical qubit. Logical qubits are used to implement algorithms to solve real-world problem. Depending on the rate that errors occur on the physical qubits, the number of physical qubits to implement a logical qubit can be higher.

For the implementation of stabilizers and thus the detection of errors, there are two types of ancilla qubits, “measure-Z” qubits and “measure-X” qubits. Their measurement outcome is commonly called “Z syndrome” and “X syndrome”. In one example, each data qubit is coupled to two measure-Z and to two measure-X qubits, and each ancilla qubit is coupled to four data qubits. Determining the measurement outcome, i.e., the eigenstate, of each syndrome allows for each data qubit the detection of possible errors. An incomplete set of surface code stabilizers allows for additional degrees of freedom, which are usable to define logical operators, which is the first step in defining a logical qubit.

The surface code selects ones of the one or more qubits, arranged in the quantum chip 10, to be ancilla qubits. The surface code selects other ones of the one or more qubits, arranged in the quantum chip 10, to be data qubits. Thereby, a subset of ancilla qubits and a subset of data qubits, of the one or more qubits is formed. The surface code associates a position of any one of the manipulation zones 20 of the quantum chip 10 with an ancilla qubit or a data qubit. In one aspect, the position may be defined by an x-coordinate and a y-coordinate (see arrows in FIG. 13A for x-direction and y-direction). In other words, the surface codes provides a mapping from the positions of the plurality of manipulation zones 20s1 to one of the subset of ancilla qubits or the subset of data qubits. In one aspect, the plurality of manipulation zones 20 may be alternatingly associated with the subset of ancilla qubits or with the subset of data qubits.

A distance between any two of the plurality of manipulation zones 20 may be defined. In one aspect, distance may be measured in nanometers. In another aspect, the distance may be determined based on a number of the T-junctions 18 arranged between the two manipulation zones 20 along a connecting one of the plurality of paths 45. Based on the distance between the two manipulation zones, a subset of neighboring ones of the plurality of manipulation zones 20 for any one manipulation zone 20 may be defined. For instance, the one manipulation zone 20 and the neighboring ones of the plurality of manipulation zones 20 may have no more than a maximum number of T-junctions 18 arranged between therebetween.

The mapping of the surface code results in an arrangement of the subset of ancilla qubits and the subset of data qubits such that any one ancilla qubit has one or more neighboring data qubits. Likewise, any one data qubit has one or more neighboring ancilla qubits.

In one example of the implementation of the surface code, one qubit may be associated with any manipulation zone 20, as indicated by the arrows in FIG. 13A. In another aspect, one or more qubits may be associated with any one of the plurality of manipulation zones 20 of the quantum chip 10.

An example of generating the mapping will now be described. In a first step 100, a first selected one 20s1 of the manipulation zones 20 is selected. A first neighboring manipulation zone 20n1 is selected. A first path 45s is selected that connects the first selected manipulation zone 20s1 and the first neighboring manipulation zone 20n1.

In a step 200, a fidelity is then calculated for a sequence of actions performed on a first qubit associated with the first selected manipulation zone 20s1 and a first neighboring qubit associated with the first neighboring manipulation zone 20n1, as described above. The sequence of comprises (a) moving the ancilla qubit along the at least one path 45s1 from the first selected manipulation zone 20s1 to the neighboring manipulation zone 20n1; (b) manipulating, at the neighboring manipulation zone 20n1, the ancilla qubit and the neighboring qubit, by performing at least one two-qubit action on the ancilla qubit and the neighboring qubit; and (c)moving the ancilla qubit along the at least one path 45s1 from the neighboring manipulation zone 20n1 to the first selected manipulation zone 20s1. The fidelity calculated for the sequence of actions is the product of the shuttling fidelity F_{S} for the path 45s1, the manipulation fidelity F_{M} at the first neighboring manipulation zone 20n1, and the shuttling fidelity F_{S} for the path 45s1. The shuttling fidelity may comprise a turning-off fidelity F_{TO}, if the path 45s1 goes past one of the T-junctions 18. In the aspect shown in FIG. 13A, the path 45s1 goes past two of the T-junctions 18.

The first neighboring manipulation 20n1 may be a nearest neighbor, i.e., there being not one manipulation zone 20 among the plurality of manipulation zones 20 of the quantum chip 10 that has a smaller distance to the first selected manipulation zone 20s1.

In a step 300, the calculated fidelity may be compared with a target value. It may be determined whether the calculated fidelity is larger than the target value. If the fidelity is not larger than the target value, an alternative path 45s2 between the first selected manipulation zone 20s1 and the first neighboring manipulation zone 20n1 is selected.

In another aspect, several paths 45s1, 45s2 may be selected at the beginning and the fidelity calculated for ones of the several paths 45s1, 45s2. The path of the several paths 45s1, 45s2 with the larger fidelity may be chosen as the path for moving the first selected qubit from the first selected manipulation zone 20s1 to the first neighboring manipulation zone 20n1.

Applying voltage pulses may increase the electron temperature due to heat entry. An increased electron temperature may reduce the fidelity due to unwanted thermal excitations. In one aspect, choosing a shuttling path 45s1 associated with a smaller fidelity compared to another shuttling path 45s2 with higher fidelity may be favorable if both fidelities are higher than a target fidelity, and if the time course of the voltage pulse to realize shuttling along the path 45s1 has a shorter duration, thus reducing the heat entry into the system.

If for the several paths 45s1, 45s2 none of fidelities associated with individual ones of the several paths 45s1, 45s2 is larger than the target value, the steps 100 and 200 may be repeated for an alternative first selected manipulation zone 20s1′. The first selected manipulation zone 20s1 may in this case not be used for operating the quantum chip 10.

The method steps 100 and 200 may be repeated on a further selected manipulation zone 20s2, which is chosen such that at least one of neighboring manipulation zones 20n of the first selected manipulation zone 20s1 is a neighboring manipulation zone 20n of the further selected manipulation zone 20s2.

The method may be repeated until all of the manipulation zones 20 have been associated with one of the subset of ancilla qubits or the subset of data qubits, or are not being used for operating the quantum chip 10. Alternatively, the method may be repeated until a predefined number of manipulation zones 20 has been associated with one of the subset of ancilla qubits or the subset of data qubits.

In another aspect, at least a first qubit of the subset of ancilla qubits or the subset of data qubits may have to be shuttled past a manipulation zone 20. The voltage pulses controlling the first shuttling element 16 and the second shuttling element 16′ forming the manipulation zone 20, meeting one another at the interface 25, are coordinated (or synchronized) in such a way, that the first shuttling element 16 and the second shuttling element 16′ allow a continuous transfer past the interface 25. In another aspect, the voltages pulses used to control the first conveyor gate assembly 50b1 of the first shuttling element 16 are identical to the voltages pulses used to control the second conveyor gate assembly 50b2 of the second shuttling element 16′. In yet another aspect, the manipulation zone 20 may be populated with at least another second qubit of the subset of ancilla qubits or the subset of data qubits. Thus, the second qubit, which is already populating the manipulation zone, may be transferred into the shuttling element opposite that shuttling element along which the first qubit is approaching the manipulation zone (20), before the first qubit may be transferred to that shuttling element. As soon as the first qubit has been transferred to the interface (25), the first and the second qubit may change places, e.g., by performing a SWAP operation. The first qubit may then be further transported, while the second qubit may remain at the manipulation zone.

Dynamical decoupling may be employed to suppress decoherence by rapid, time-dependent control modulation of the time sequence of the voltage pulses. In one aspect, a sequence of actions suitable for dynamical decoupling may be chosen to be compatible with quantum gates operations. In another aspect, the Carr-Purcell and/or the Carr-Purcell-Meiboom-Gill schemes may be employed. These schemes may be based on the Hahn spin echo technique, by applying periodic pulses to enable refocusing. In another aspect, idle qubits, which are qubits of the subset of ancilla qubits or the subset of data qubits, for which all necessary actions have already been performed, while actions are still being performed on at least one other qubit of the subset of ancilla qubits or the subset of data qubits, may perform actions suitable for dynamical decoupling, e.g., a Carr-Purcell-Meiboom-Gill scheme.

Coordination of time courses of signals applied to electrodes describes the necessary coordination of various different types of time courses, e.g., varying in length in time, voltage amplitude and voltage ramps. While various time courses can be of similar length, there may always be one specific point along such a time course, where sometimes courses have to be in synchronization with others. In this context, synchronization can mean the arrangement of multiple voltages applied to electrodes which create a sinusoidal voltage signal of exact same magnitude and frequency, but may only differ by a relative phase which is constant during the synchronized time course such as used for the described shuttling element. On the other hand, time courses of signals, used for completely different operations such as shuttling versus a CPMG pulse sequence, may be asynchronous with respect to each other.

Coordination of these time courses and the respective coordination of the voltage signals defines the specific part of time courses whereat these signals have to be synchronous to other predefined signal courses. In yet another aspect, while a at least a first qubit of the subset of ancilla qubits or the subset of data qubits may be shuttled, an at least second qubit of the subset of ancilla qubits or the subset of data qubits may perform a CPMG sequence. Here, both time course signals can be asynchronous. However, at the specific point on time when the first qubit arrives at the manipulation zone associated with the second qubit, the CPMG sequence performed on the qubit has to be finished. Subsequently a two-qubit manipulation can be performed for both the first and the second qubit.

Different control signals are required for the operation of a Quantum Computing chip. These signals are divided into DC with constant voltage and AC with oscillating signals and are generated in signal sources. Each signal source can provide multiple channels. Depending on the gate design of the chip, these signals are applied to different electrodes. The connection between the signal sources (or more specific between channels of a signal source) and the electrodes is done by cables between the signal source.

1. A method, using a microprocessor, of operating a quantum chip (10),
wherein the quantum chip comprises a semiconductor heterostructure (12) and a plurality of gate electrodes (50) arranged on the semiconductor heterostructure (12) to provide a plurality of shuttling lanes (16) for moving a plurality of qubits along a plurality of paths (45);
the plurality of gate electrodes (50) are further arranged to form a plurality of manipulation zones (20) and a plurality of T-junctions (18),
any one of the plurality of manipulation zones (20) comprising an interface (25), at which two of the plurality of shuttling lanes (16) meet one another, and
any one of the plurality of T-junctions (18) comprising a junction (28), at which one of the plurality of shuttling lanes (16) joins another one of the plurality of shuttling lanes (16);
the method comprising the steps of
calibrating voltage parameters pertaining to voltages to be applied to the plurality of gate electrodes (50), the parameters pertaining to one or more subgroups of the plurality of gate electrodes (50);
selecting a path (45s) along selected ones (16-1, 16-2, . . . , 16-n) of the plurality of shuttling lanes (16) between a position (S) of a qubit and a selected manipulation zone (20);
determining, based on the voltage parameters, for any one of the selected ones (16-1, 16-2, . . . , 16-n) of the plurality of shuttling lanes (16), at least one shuttling voltage time course to be applied to the associated subset (50i) of the plurality of gate electrodes (50), to move the qubit from the current position to the selected manipulation zone (20);
moving the qubit along the selected ones (16-1, 16-2, . . . , 16-n) of the plurality of shuttling lanes (16) from the current position(S) to the selected manipulation zone (20), by applying the shuttling voltage time courses to subsets (50-1, 50-2, . . . , 50-n) of the plurality of gate electrodes (50), associated with the selected ones (16-1, 16-2, . . . , 16-n) of the plurality of shuttling lanes (16);
determining, based on the voltage parameters, for the selected manipulation zone (20) a manipulation voltage time course to be applied to the associated subsets (50-n, 50-s) of the plurality of gate electrodes (50), to manipulate the qubit; and
manipulating the qubit at the selected manipulation zone (20) by applying at least one manipulation voltage time course to the subsets (50-n,50-s) of the plurality of gate electrodes (50), associated with the selected manipulation zone (20).

2. The method of claim 1, wherein the manipulating of the qubit comprises performing a single-qubit action on the qubit.

3. The method of claim 1, wherein the manipulating of the qubit comprises performing a two-qubit action on the qubit and a second qubit positioned at the selected manipulation zone (20).

4. The method of claim 1, further comprising moving the qubit to the position (S).

5. The method of claim 1, wherein the path (45s) is selected such that at least two of the selected ones (16-1, 16-2, . . . , 16-n) of the plurality of shuttling lanes (16) meet at the interface (25) of at least one interposed one (20) of the plurality of manipulation zones (20), or join at the junction (28i) of at least one interposed one (18) of the plurality of T-junctions (18).

6. The method of claim 3, further comprising moving a third qubit, positioned at the selected manipulation zone (20), from the selected manipulation zone (20) by applying at least one further shuttling voltage time course to the subsets (50-n,50-s) of the plurality of gate electrodes (50), associated with the selected manipulation zone (20).

7. The method of claim 6, wherein the moving of the third qubit, positioned at the selected manipulation zone (20), comprises moving the third qubit past the interface (25) of the selected manipulation zone (20).

8. The method of claim 1, moving another qubit along further selected ones (16-1′, 16-2′, . . . , 16-n′) of the plurality of shuttling lanes (16), by applying the shuttling voltage time courses to further subsets (50-1′, 50-2′, . . . , 50-n′) of the plurality of gate electrodes (50), associated with the further selected ones (16-1′, 16-2′, . . . , 16-n′) of the plurality of shuttling lanes (16).

9. The method of claim 1, further comprising manipulating the other qubit at a further manipulation zone (20′), by applying the at least one manipulation voltage time course to further subsets (50-n′,50-s′) of the plurality of gate electrodes (50), associated with the further manipulation zone (20′.)

10. The method of claim 1, further comprising coordinating the applying of the shuttling voltage time courses, the applying of the manipulation voltage time course, and the applying of the at least one further shuttling voltage time course.

11. The method of claim 10, further comprising coordinating further voltage time courses applied to other ones of the plurality of gate electrodes (50).

12. The method of claim 1, further comprising recalibrating and/or adjusting the voltage parameters.

13. The method of claim 1, further comprising improving a coherence of one of the qubits.

14. The method of claim 13, wherein the improving of the coherence comprises applying dynamical decoupling.

15. A computing system comprising a quantum processor, a voltage source, and a microprocessor,
the quantum chip comprising a semiconductor heterostructure and a plurality of gate electrodes arranged on the semiconductor heterostructure, wherein
a) the plurality of gate electrodes are arranged to provide a plurality of manipulation zones for manipulating a plurality of qubits, a plurality of T-junctions for interconnecting the plurality of qubits, and a plurality of shuttling lanes which provide a plurality of paths along which the plurality of qubits are movable, and
b) the plurality of manipulation zones are interconnected by the plurality of paths and the plurality of T-junctions,
the voltage source being electrically connected to the plurality of gate electrodes to apply voltages to the plurality of gate electrodes for manipulating the plurality of qubits, for interconnecting the plurality of qubits, and/or for moving the plurality of qubits; and
the microprocessor being communicatively connected to the voltage source for controlling the voltages and comprising a memory storing voltage parameters for voltages to be applied, the parameters pertaining to one or more subgroups of the plurality of gate electrodes.

16. The computing system of claim 15, wherein any one of the plurality of manipulation zones has an interface, at which two meeting ones of the plurality of shuttling lanes meet one another.

17. The computing system of claim 16, wherein ones of the manipulation zone further comprise at least one plunger gate and/or at least one barrier gate at the interface.

18. The computing system of claim 15, wherein any one of the plurality of T-junctions has a junction at which two joining ones of the plurality of shuttling lanes join one another.

19. The computing system of claim 18, wherein ones of the plurality of T-junctions further comprise at least one plunger gate and/or at least one barrier gate at the junction.

20. The computing system of claim 15, wherein at least one of the plurality of manipulation zones further comprises a top gate.

21. The computing system of claim 15, wherein the voltage source is configured to provide at least one DC voltage and/or at least one AC voltage.

22. The computing system of claim 15, wherein the quantum processor is arranged at a first cryogenic temperature.

23. The computing system of claim 15, wherein the microprocessor is arranged at an ambient temperature or at a second cryogenic temperature, the second cryogenic temperature being equal to, or different from, the first cryogenic temperature.

24. The computing system of claim 15, wherein the plurality of gate electrodes are arranged on the semiconductor heterostructure in a periodic manner.

25. System comprising the computing system of claim 15 and an external magnet for providing an external magnetic field B₀.
